(19) United States
(12) Patent Application Publication
(10) Pub. No.: US 2025/0351676 A1
(43) Pub. Date: Nov. 13, 2025

(54) Electronic Device with an Under-Display Sensor

(71) Applicant: Apple Inc., Cupertino, CA (US)

(72) Inventors: Wenbing Hu, Campbell, CA (US); Jean-Pierre S. Guillou, La Jolla, CA (US); Paul C. Kelley, San Francisco, CA (US); Yi Qiao, San Jose, CA (US); Salman Karbasi, San Jose, CA (US); Abbas Jamshidi Roudbari, Saratoga, CA (US); Warren S. Rieutort-Louis, Cupertino, CA (US); Yuchi Che, Santa Clara, CA (US); Graeme M. Williams, Toronto (CA); Jie Won Ryu, San Jose, CA (US); Hari P. Paudel, Fremont, CA (US); Feng Wen, Cupertino, CA (US); Muqing Liu, San Jose, CA (US); Kyounghwan Kim, San Jose, CA (US); Joy M. Johnson, Oakland, CA (US)

(21) Appl. No.: 19/197,057

(22) Filed: May 2, 2025

Related U.S. Application Data
(60) Provisional application No. 63/643,545, filed on May 7, 2024.
(60) Provisional application No. 63/659,622, filed on Jun. 13, 2024.

(51) Int. Cl. H10K 59/121; G09G 3/32; H10K 59/131; H10K 59/35

(52) U.S. Cl. CPC H10K 59/1213; G09G 3/32; H10K 59/131; H10K 59/353; G09G 2300/0413; G09G 2300/0452

(57) ABSTRACT

A display may overlap a sensor such as a camera or ambient light sensor. A portion of the display that overlaps the sensor may be modified to increase transparency relative to the remaining portion of the display. The modified portion of the display may have pixel islands that conform to a regular grid pattern of the remaining portion of the display. One or more gate lines and/or one or more data lines may pass through the modified portion of the display without connecting to any subpixels in the modified portion of the display. An opaque pixel definition layer may include some openings that are aligned with opaque masking layer openings to allow on-axis light to pass through to a sensor and some openings that are offset relative to respective opaque masking layer openings to allow off-axis light to pass through to the sensor.

This application claims the benefit of U.S. provisional patent application No. 63/643,545, filed May 7, 2024, and U.S. provisional patent application No. 63/659,622, filed Jun. 13, 2024, which are hereby incorporated by reference herein in their entireties.

### BACKGROUND

This relates generally to electronic devices, and, more particularly, to electronic devices with displays.

Electronic devices often include displays. For example, an electronic device may have a light-emitting diode (LED) display based on light-emitting diode pixels. In this type of display, each pixel includes a light-emitting diode and circuitry for controlling application of a signal to the light-emitting diode to produce light.

There is a trend towards borderless electronic devices with a full-face display. These devices, however, may still need to include sensors such as cameras, ambient light sensors, and proximity sensors to provide other device capabilities. Since the display now covers the entire front face of the electronic device, the sensors will have to be placed under the display stack.

It is within this context that the embodiments herein arise.

### SUMMARY

An electronic device may include a sensor and a display comprising a first portion that overlaps the sensor and a second portion that does not overlap the sensor. The second portion may include an array of pixels that includes subpixels arranged according to a regular grid of rows and columns, the first portion may include a plurality of subpixel islands that each include at least one subpixel, a total number of subpixels per unit area may be lower in the first portion than in the second portion, and the subpixels in the subpixel islands may be part of the regular grid of rows and columns.

An electronic device may include a sensor and a display comprising an array of pixels, a first opaque layer, and a second opaque layer that overlaps the first opaque layer. A portion of the display that overlaps the sensor may include a first plurality of openings in the second opaque layer, a second plurality of openings in the first opaque layer, and a third plurality of openings in the first opaque layer. Each one of the second plurality of openings may be aligned with a respective one of the first plurality of openings, each one of the second plurality of openings may be offset relative to a respective one of the first plurality of openings, and each one of the first, second, and third pluralities of openings may be interposed between adjacent subpixels within the array of pixels.

An electronic device may include a camera and a display comprising a first portion that overlaps the camera and a second portion that does not overlap the camera. The second portion may include an array of pixels that include subpixels arranged according to a regular grid of rows and columns, a total number of subpixels per unit area may be lower in the first portion than in the second portion, the first portion may include subpixels that conform to the regular grid, and at least one data line may pass through the first portion without electrically connecting to any subpixels in the first portion.

An electronic device may include a sensor and a display comprising pixels. The pixels may include subpixels, the subpixels may include emissive subpixels that emit light and thin-film transistor subpixels that control the emissive sub-pixels, the emissive subpixels may be arranged in a regular grid of rows and columns, the display may have a first portion that overlaps the sensor and a second portion that does not overlap the sensor, the first portion may include a plurality of subpixel groups that each include at least one subpixel, each one of the plurality of subpixel groups in the first portion may include a thin-film transistor subpixel that controls two or more emissive subpixels, a total number of emissive subpixels per unit area may be lower in the first portion than in the second portion, and the emissive subpixels in the subpixel groups may be part of the regular grid of rows and columns.

### BRIEF DESCRIPTION OF THE DRAWINGS

FIG. 1 is a schematic diagram of an illustrative electronic device having a display and one or more sensors in accordance with some embodiments.

FIG. 2 is a schematic diagram of an illustrative display with light-emitting elements in accordance with some embodiments.

FIGS. 3A-3F are top views of illustrative displays showing possible positions for locally modified regions in accordance with some embodiments.

FIG. 4 is a top view of an illustrative normal display region with an array of pixels arranged in a regular grid in accordance with some embodiments.

FIG. 5 is a top view of an illustrative modified display region with pixel islands, two functional gate lines per three input gate lines, and four functional data lines per five input data lines in accordance with some embodiments.

FIG. 6 is a top view of an illustrative modified display region with pixel islands, one functional gate line per two input gate lines, and four functional data lines per four input data lines in accordance with some embodiments.

FIG. 7 is a top view of an illustrative modified display region with pixel islands, one functional gate line per two input gate lines, and four functional data lines per six input data lines in accordance with some embodiments.

FIG. 8 is a top view of an illustrative modified display region with pixel islands, one functional gate line per two input gate lines, and four functional data lines per four input data lines in accordance with some embodiments.

FIG. 9 is a top view of an illustrative modified display region with horizontal subpixel strips in accordance with some embodiments.

FIG. 10 is a top view of an illustrative modified display region with vertical subpixel strips in accordance with some embodiments.

FIG. 11 is a top view of an illustrative display with a normal region, a modified region, and a transition region between the modified region and the normal region in accordance with some embodiments.

FIG. 12 is a graph of an illustrative profile for a property as a function of position within a display in accordance with some embodiments.

FIG. 13 is a graph of an illustrative profile for maximum luminance as a function of position within a display in accordance with some embodiments.

FIG. 14 is a top view of an illustrative display with a modified region and dimmed pixel regions outside the modified region in accordance with some embodiments.

FIG. 15 is a top view of an illustrative modified region of a display in accordance with some embodiments.

FIG. 16 is a top view of an illustrative modified region of a display with opaque pixel definition layer openings that are aligned with opaque masking layer openings in accordance with some embodiments.

FIG. 17 is a cross-sectional side view of the illustrative modified region of FIG. 16 in accordance with some embodiments.

FIG. 18 is a top view of an illustrative modified region of a display with some opaque pixel definition layer openings that are aligned with opaque masking layer openings and some L-shaped opaque pixel definition layer openings that are offset relative to respective opaque masking layer openings in accordance with some embodiments.

FIG. 19 is a cross-sectional side view of the illustrative modified region of FIG. 18 in accordance with some embodiments.

FIG. 20 is a top view of an illustrative modified region of a display with some opaque pixel definition layer openings that are aligned with opaque masking layer openings and some ring-shaped opaque pixel definition layer openings that are offset relative to respective opaque masking layer openings in accordance with some embodiments.

FIG. 21 is a cross-sectional side view of the illustrative modified region of FIG. 20 in accordance with some embodiments.

FIG. 22 is a top view of an illustrative modified display region with subpixel groups that each include five thin-film transistor subpixels for seven emissive subpixels in accordance with some embodiments.

FIG. 23 is a top view of an illustrative modified display region with subpixel groups that each include three thin-film transistor subpixels for seven emissive subpixels in accordance with some embodiments.

FIGS. 24A and 24B are top views of an illustrative subpixel group with thin-film transistor subpixels and shorted emissive subpixels in accordance with some embodiments.

FIG. 25 is a top view of an illustrative modified display region with subpixel groups of two different layouts in alternating rows in a checkerboard pattern in accordance with some embodiments.

FIG. 26 is a top view of an illustrative modified display region with subpixel groups that each include six emissive subpixels in accordance with some embodiments.

FIG. 27 is a top view of the illustrative modified display region of FIG. 22 showing data line routing through the modified display region in accordance with some embodiments.

FIG. 28 is a top view of the illustrative modified display region of FIG. 23 showing data line routing through the modified display region in accordance with some embodiments.

FIG. 29 is a top view of an illustrative display with signal lines routed around a modified display region in accordance with some embodiments.

FIG. 30 is a cross-sectional side view of a dummy subpixel in accordance with some embodiments.

### DETAILED DESCRIPTION

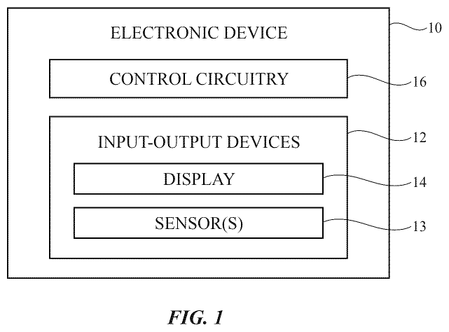

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid-state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

Input-output devices 12 may also include one or more sensors 13 such as force sensors (e.g., strain gauges, capacitive force sensors, resistive force sensors, etc.), audio sensors such as microphones, touch and/or proximity sensors such as capacitive sensors (e.g., a two-dimensional capacitive touch sensor associated with a display and/or a touch sensor that forms a button, trackpad, or other input device not associated with a display), and other sensors. In accordance with some embodiments, sensors 13 may include optical sensors such as optical sensors that emit and detect light (e.g., optical proximity sensors such as transreflective optical proximity structures), ultrasonic sensors, and/or other touch and/or proximity sensors, monochromatic and color ambient light sensors, image sensors, fingerprint sensors, temperature sensors, proximity sensors and other sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 13 and/or other input-output devices to gather user input (e.g., buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.).

Display 14 may be an organic light-emitting diode display, a display formed from an array of discrete light-emitting diodes (microLEDs) each formed from a crystalline semiconductor die, a liquid crystal display or any other suitable type of display. Device configurations in which display 14 is an organic light-emitting diode display are sometimes described herein as an example. This is, however, merely illustrative. Any suitable type of display may be used, if desired. In general, display 14 may have a rectangular shape (i.e., display 14 may have a rectangular footprint and a rectangular peripheral edge that runs around the rectangular footprint) or may have other suitable shapes. Display 14 may be planar or may have a curved profile.

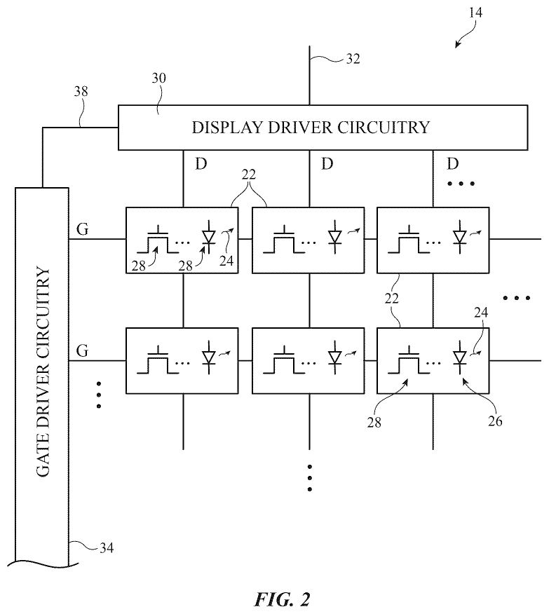

A top view of a portion of display 14 is shown in FIG. 2. As shown in FIG. 2, display 14 may have an array of pixels 22 formed on a substrate. Pixels 22 may receive data signals over signal paths such as data lines D and may receive one or more control signals over control signal paths such as horizontal control lines G (sometimes referred to as gate lines, scan lines, emission control lines, etc.). There may be any suitable number of rows and columns of pixels 22 in display 14 (e.g., tens or more, hundreds or more, or thousands or more). Each pixel 22 may include a light-emitting diode 26 that emits light 24 under the control of a pixel control circuit formed from thin-film transistor circuitry such as thin-film transistors 28 and thin-film capacitors. Thin-film transistors 28 may be polysilicon thin-film transistors, semiconducting-oxide thin-film transistors such as indium zinc gallium oxide (IGZO) transistors, or thin-film transistors formed from other semiconductors. Pixels 22 may contain light-emitting diodes of different colors (e.g., red, green, and blue) to provide display 14 with the ability to display color images or may be monochromatic pixels.

Display driver circuitry may be used to control the operation of pixels 22. The display driver circuitry may be formed from integrated circuits, thin-film transistor circuits, or other suitable circuitry. Display driver circuitry 30 of FIG. 2 may contain communications circuitry for communicating with system control circuitry such as control circuitry 16 of FIG. 1 over path 32. Path 32 may be formed from traces on a flexible printed circuit or other cable. During operation, the control circuitry (e.g., control circuitry 16 of FIG. 1) may supply display driver circuitry 30 with information on images to be displayed on display 14.

To display the images on display pixels 22, display driver circuitry 30 may supply image data to data lines D while issuing clock signals and other control signals to supporting display driver circuitry such as gate driver circuitry 34 over path 38. If desired, display driver circuitry 30 may also supply clock signals and other control signals to gate driver circuitry 34 on an opposing edge of display 14.

Gate driver circuitry 34 (sometimes referred to as row control circuitry) may be implemented as part of an integrated circuit and/or may be implemented using thin-film transistor circuitry. Horizontal control lines G in display 14 may carry gate line signals such as scan line signals, emission enable control signals, and other horizontal control signals for controlling the display pixels 22 of each row. There may be any suitable number of horizontal control signals per row of pixels 22 (e.g., one or more row control signals, two or more row control signals, three or more row control signals, four or more row control signals, etc.).

The region on display 14 where the display pixels 22 are formed may sometimes be referred to herein as the active area. Electronic device 10 has an external housing with a peripheral edge. The region surrounding the active area and within the peripheral edge of device 10 is the border region. Images can only be displayed to a user of the device in the active region. It is generally desirable to minimize the border region of device 10. For example, device 10 may be provided with a full-face display 14 that extends across the entire front face of the device. If desired, display 14 may also wrap around over the edge of the front face so that at least part of the lateral edges or at least part of the back surface of device 10 is used for display purposes.

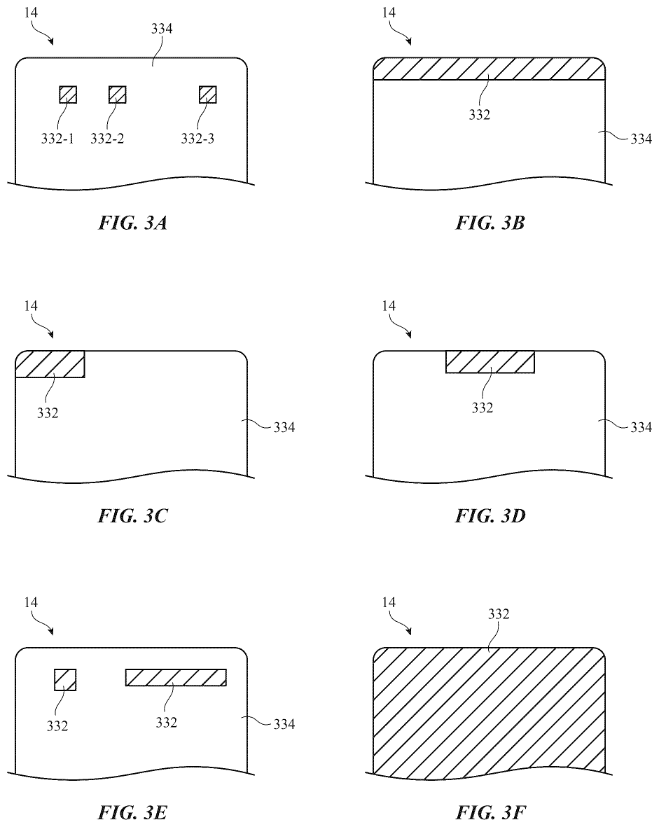

Device 10 may include a sensor 13 mounted behind display 14 (e.g., behind the active area of the display). FIGS. 3A-3F are top views of illustrative displays 14 with a sensor 13 mounted behind the active area (AA) of the display. In some cases, the majority of display 14 may have the same layout. The pixel layout used for the majority of the display may sometimes be referred to as a base layout, majority layout, or normal layout. Portions of display 14 that overlap an input-output component such as sensor 13 may be modified relative to the base layout. In particular, the portions of display 14 that overlap an input-output component may be modified to have a higher transparency than the base layout.

In general, the display may be modified to have an increased transparency in any region(s) of display 14. FIGS. 3A-3F are front views showing how display 14 may have one or more locally modified regions in which the display is modified to increase transparency. The example of FIG. 3A illustrates various locally modified regions 332 physically separated from one another (i.e., the various locally modified regions 332 are non-continuous) by normal display region 334. The locally modified regions 332 may have some modification relative to normal display region 334 that increase transparency. These regions may therefore sometimes be referred to as increased-transparency regions 332, high-transparency regions 332, etc. The normal display region 334 may sometimes be referred to as low-transparency region 334, opaque region 334, etc.

The three locally modified regions 332-1, 332-2, and 332-3 in FIG. 3A might for example correspond to three different sensors formed underneath display 14 (with one sensor per locally modified region). Any portion of the display that is within the field-of-view of an underlying sensor may be modified to increase transparency.

The example of FIG. 3B illustrates a continuous locally modified region 332 formed along the top border of display 14, which might be suitable when there are many optical sensors positioned near the top edge of device 10. The example of FIG. 3C illustrates a locally modified region 332 formed at a corner of display 14 (e.g., a rounded corner area of the display). In some arrangements, the corner of display 14 in which locally modified region 332 is located may be a rounded corner (as in FIG. 3C) or a corner having a substantially 90° corner. The example of FIG. 3D illustrates a locally modified region 332 formed only in the center portion along the top edge of device 10 (i.e., the locally modified region covers a recessed notch area in the display). FIG. 3E illustrates another example in which locally modified regions 332 can have different shapes and sizes. FIG. 3F illustrates yet another suitable example in which the locally modified region covers the entire display surface. In other words, the entire display may have a high transparency as will be later discussed. These examples are merely illustrative and are not intended to limit the scope of the present embodiments. If desired, any one or more portions of the display overlapping with optically based sensors or other sub-display electrical components may be designated as a locally modified region to increase transparency.

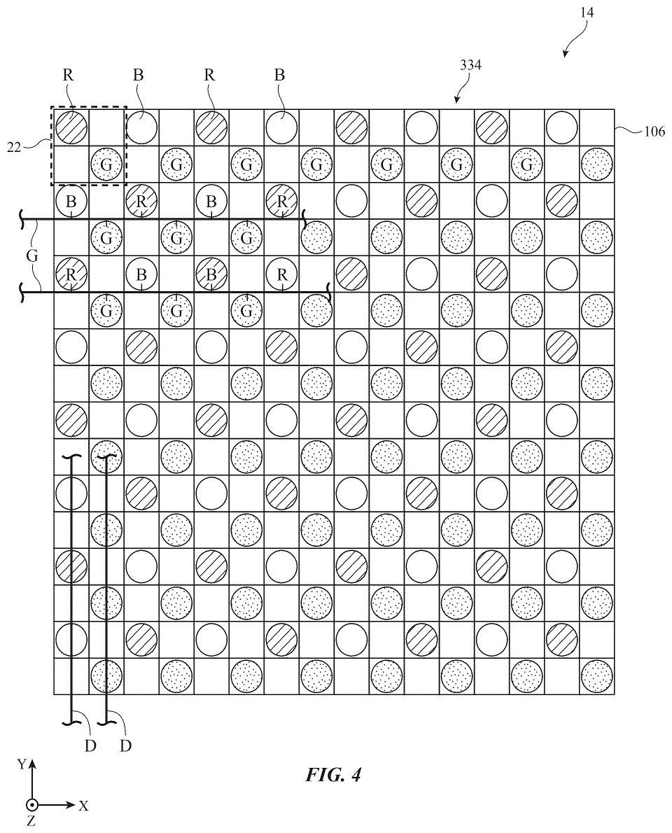

FIG. 4 is a top view of an illustrative normal display region 334. As shown in FIG. 4, in normal display region 334 display 14 includes red subpixels R, blue subpixels B, and green subpixels G. The subpixels are arranged in rows and columns. In half of the subpixel rows, red and blue subpixels alternate with one column without any subpixels interposed between adjacent subpixels. For example, in the top row of FIG. 4, the first column has a red subpixel, the second column has no subpixels, the third column has a blue subpixel, the fourth column has no subpixels, etc.

In the remaining half of the rows, green subpixels alternate with one column without any subpixels interposed between adjacent subpixels. For example, in the second-from-top row of FIG. 4, the first column has no subpixels, the second column has a green subpixel, the third column has no subpixels, the fourth column has a green subpixel, etc.

In other words, in the normal display region the subpixels have a checkerboard pattern that is arranged in a regular grid 106 of rows and columns. The rows extend in the X-direction and the columns extend in the Y-direction. The grid may be described as comprising a plurality of grid squares, with half of the grid squares in FIG. 4 occupied by a subpixel and half of the grid squares in FIG. 4 unoccupied by a subpixel.

It is noted that the subpixels of normal display region 334 may be grouped into pixels in any desired manner. In FIG. 4, each pixel 22 includes four squares of the grid pattern: two subpixels and two squares that do not include any subpixels. In other words, half of the pixels include one red subpixel and one green subpixel and half of the pixels include one blue subpixel and one green subpixel. This example is merely illustrative. In general, the emissive subpixels of one or more pixels may extend past the borders of their respective grid squares. The center of the emissive subpixels may be aligned with the centers of their respective grid squares.

FIG. 4 also shows how display 14 includes both gate lines and data lines. As shown, each column of subpixels may have a respective data line D. The data lines for half of the subpixels provide pixel brightness data to red and blue subpixels. The data lines for half of the subpixels provide pixel brightness data to green subpixels.

As shown, each row of pixels may have a respective gate line G. A single gate line therefore provides gate signals to two rows of subpixels. As shown in FIG. 4, each gate line provides gate signals to red, blue, and green subpixels in two subpixel rows.

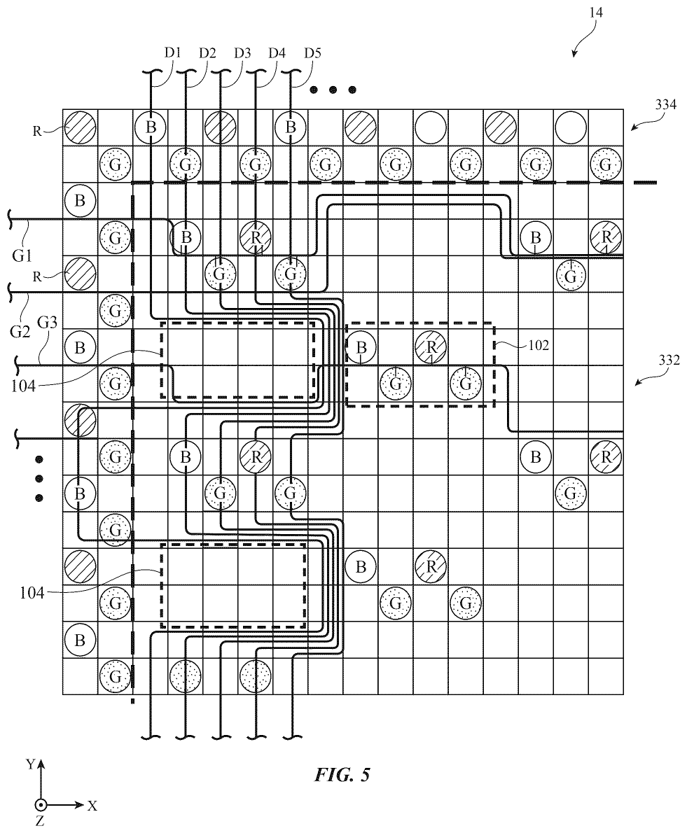

To increase the transparency of display region 332 relative to display region 334, pixels may be omitted in display region 332 relative to display region 334. FIGS. 5-10 show various arrangements for modified display regions 332 with increased transparency relative to normal display region 334.

As shown in FIGS. 5-8, modified display region 332 may include a plurality of pixel regions 102 (sometimes referred to as pixel islands, pixel groups, subpixel regions, subpixel islands, subpixel groups, repeating unit 102, etc.) as well as non-pixel regions 104 (sometimes referred to as windows, transparent regions, etc.).

In FIG. 5, each pixel island 102 includes two rows of subpixels and four columns of subpixels. The first row of subpixels includes a blue subpixel in the first column and a red subpixel in the third column. The second row of subpixels includes a green subpixel in the second column and a green subpixel in the fourth column.

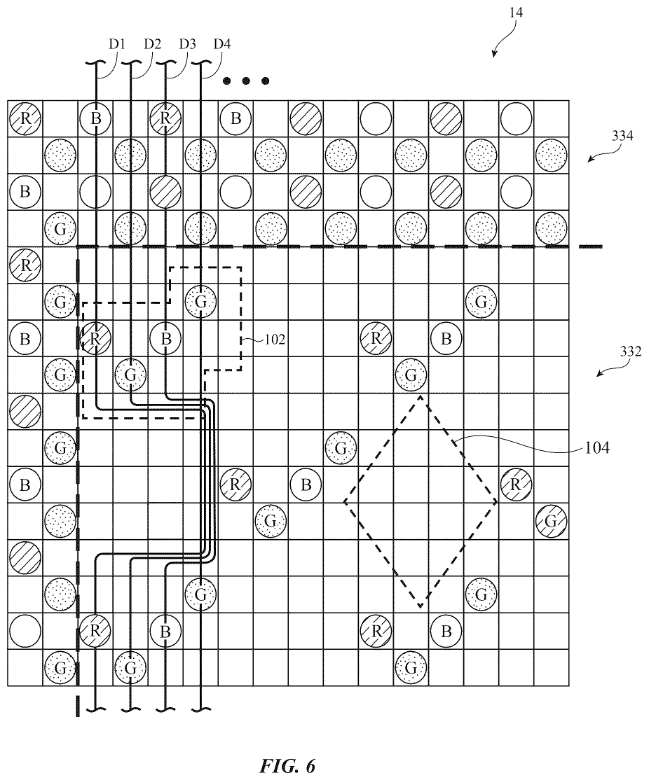

In FIG. 6, each pixel island 102 includes three rows of subpixels and four columns of subpixels. The first row of subpixels includes a green subpixel in the fourth column. The second row of subpixels includes a red subpixel in the first column and a blue subpixel in the third column. The third row of subpixels includes a green subpixel in the second column.

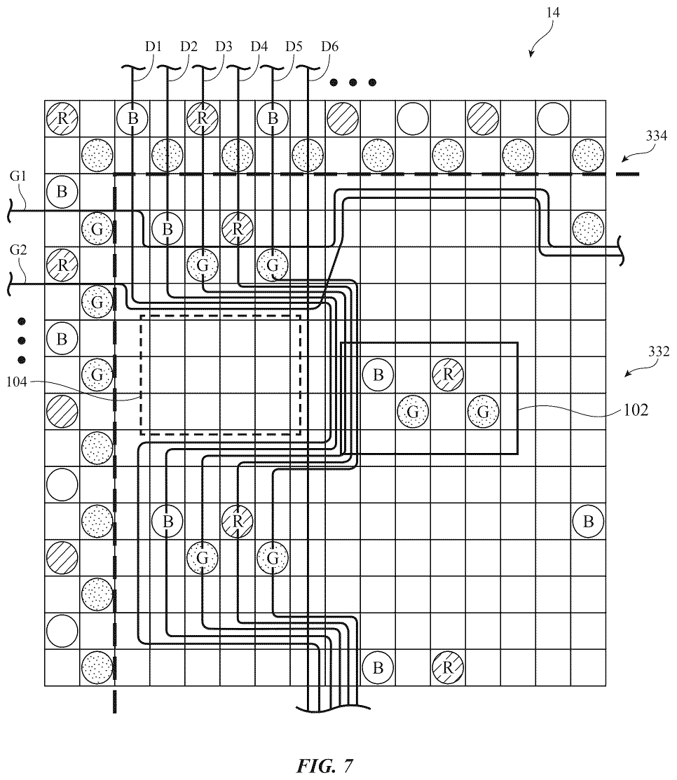

In FIG. 7, each pixel island 102 includes two rows of subpixels and four columns of subpixels. The first row of subpixels includes a blue subpixel in the first column and a red subpixel in the third column. The second row of subpixels includes a green subpixel in the second column and a green subpixel in the fourth column.

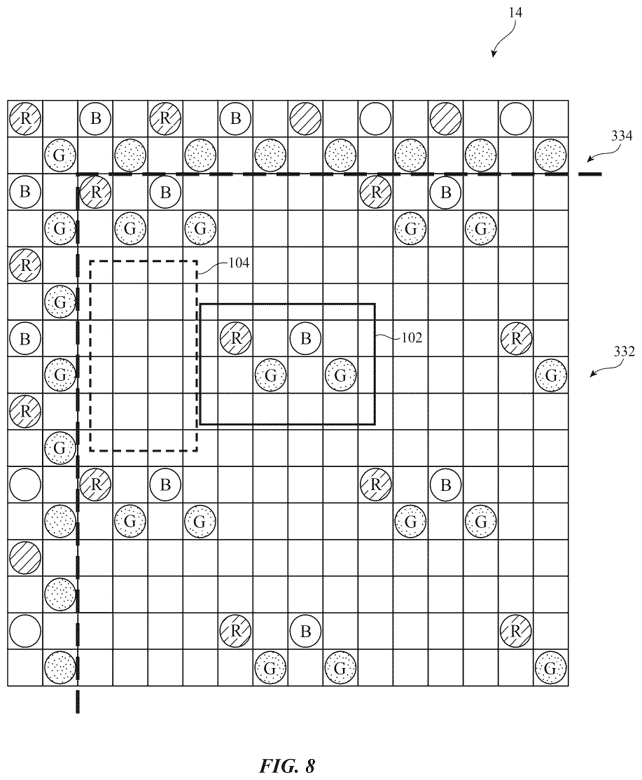

In FIG. 8, each pixel island 102 includes two rows of subpixels and four columns of subpixels. The first row of subpixels includes a red subpixel in the first column and a blue subpixel in the third column. The second row of subpixels includes a green subpixel in the second column and a green subpixel in the fourth column.

In FIGS. 5-8, the pixel islands are arranged in a checkerboard pattern. In FIG. 5, adjacent pixel islands within a common row of pixel islands are separated by six grid squares that are unoccupied by any subpixels. Adjacent pixel islands within a common column of pixel islands are separated by four grid squares that are unoccupied by any subpixels. Consequently, there is one entirely unoccupied column of grid squares between adjacent columns of pixel islands in region 332 and one entirely unoccupied row of grid squares between adjacent rows of pixel islands in region 332.

In FIG. 6, adjacent pixel islands within a common row of pixel islands are separated by four grid squares that are unoccupied by any subpixels. Adjacent pixel islands within a common column of pixel islands are separated by five grid squares that are unoccupied by any subpixels. Consequently, there are no entirely unoccupied columns of grid squares between adjacent columns of pixel islands in region 332 (e.g., the right-most subpixel of a pixel island in a first column of the pixel islands is in an adjacent grid column to the left-most subpixel of a pixel island in a second, adjacent column of pixel islands). There is one entirely unoccupied row of grid squares between adjacent rows of pixel islands in region 332.

In FIG. 7, adjacent pixel islands within a common row of pixel islands are separated by eight grid squares that are unoccupied by any subpixels. Adjacent pixel islands within a common column of pixel islands are separated by six grid squares that are unoccupied by any subpixels. Consequently, there are two entirely unoccupied columns of grid squares between adjacent columns of pixel islands in region 332. There are two entirely unoccupied rows of grid squares between adjacent rows of pixel islands in region 332.

In FIG. 8, adjacent pixel islands within a common row of pixel islands are separated by four grid squares that are unoccupied by any subpixels. Adjacent pixel islands within a common column of pixel islands are separated by six grid squares that are unoccupied by any subpixels. Consequently, there are no unoccupied columns of grid squares between adjacent columns of pixel islands in region 332. There are two entirely unoccupied rows of grid squares between adjacent rows of pixel islands in region 332.

With the arrangement of FIG. 5, only two gate lines within modified region 332 are functional for every three input gate lines from normal region 334. As shown in FIG. 5, display 14 may include a first gate line G1 associated with a first pixel row in normal region 334, a second gate line G2 associated with a second pixel row in normal region 334, and a third gate line G3 associated with a third pixel row in normal region 334. Within the normal region 334, gate lines G1, G2, and G3 may be parallel and straight. Within modified region 332, gate line G1 provides gate signals to subpixels in a first row of pixel islands and gate line G3 provides gate signals to subpixels in a second row of pixel islands. In other words, gate lines G1 and G3 are functional (e.g., provide gate signals to subpixels) within modified region 332. In contrast, gate line G2 does not provide gate signals to any subpixels within modified region 332 and may therefore be referred to as non-functional within modified region 332. Gate line G2 may also be referred to as a bypass gate/signal line or passthrough gate/signal line for modified region 332. This pattern of functional gate lines G1 and G3 and a non-functional gate line G2 may be repeated across the modified region 332. The example of odd gate lines being functional in modified region 332 and even gate lines being non-functional in modified region 332 is merely illustrative. If desired, odd gate lines may be non-functional in modified region 332 and even gate lines may be functional in modified region 332.

It is noted that there may be multiple gate lines for each row pixels within normal display region 334 and/or modified display region 332. Gate line G1 and G2 may refer to groups of gate lines that include all of the gate signals for operating the display pixels. For simplicity, only one gate line is shown for each gate line group herein.

With the arrangement of FIG. 7, only one gate line within modified region 332 is functional for every two input gate lines from normal region 334. As shown in FIG. 7, display 14 may include a first gate line G1 associated with a first pixel row in normal region 334 and a second gate line G2 associated with a second pixel row in normal region 334. Within the normal region 334, gate lines G1 and G2 may be parallel and straight. Within modified region 332, gate line G1 provides gate signals to subpixels in a first row of pixel islands. In other words, gate line G1 is functional (e.g., provide gate signals to subpixels) within modified region 332. In contrast, gate line G2 does not provide gate signals to any subpixels within modified region 332 and may therefore be referred to as non-functional within modified region 332. Gate line G2 may also be referred to as a bypass gate/signal line or passthrough gate/signal line for modified region 332. This pattern of functional gate lines G1 alternating with non-functional gate lines G2 may be repeated across the modified region 332.

With the arrangement of FIG. 6, only one gate line within modified region 332 is functional for every two input gate lines from normal region 334 (similar to as shown and described in connection with FIG. 7).

With the arrangement of FIG. 8, only one gate line within modified region 332 is functional for every two input gate lines from normal region 334 (similar to as shown and described in connection with FIG. 7).

To maximize the size and/or transparency of non-pixel regions 104, gate lines G may have one or more turns within modified region 332. As shown in FIGS. 5 and 7, the gate lines may include multiple turns in the positive and/or negative Y-directions while extending across the modified region 332 in the X-direction. The turns in the gate lines may allow for the gate lines to be consolidated adjacent to the pixel islands, thus maximizing the size and/or transparency of non-pixel regions 104.

With the arrangement of FIG. 5, only four data lines within modified region 332 are functional for every five input data lines from normal region 334. As shown in FIG. 5, display 14 may include a first data line D1 associated with a first subpixel column in normal region 334, a second data line D2 associated with a second subpixel column in normal region 334, a third data line D3 associated with a third subpixel column in normal region 334, a fourth data line D4 associated with a fourth subpixel column in normal region 334, and a fifth data line D5 associated with a fifth subpixel column in normal region 334. Within the normal region 334, data lines D1, D2, D3, D4, and D5 may be parallel and straight. Within modified region 332, data line D2 provides brightness data signals to subpixels in the second subpixel column, data line D3 provides brightness data signals to subpixels in the third subpixel column, data line D4 provides brightness data signals to subpixels in the fourth subpixel column, and data line D5 provides brightness data signals to subpixels in the fifth subpixel column. In other words, data lines D2, D3, D4, and D5 are functional (e.g., provide data brightness signals to subpixels) within modified region 332. In contrast, data line D1 does not provide data signals to any subpixels within modified region 332 and may therefore be referred to as non-functional within modified region 332. Data line D1 may also be referred to as a bypass data/signal line or passthrough data/signal line for modified region 332. This pattern of functional data lines D2-D5 and a non-functional data line D1 may be repeated across the modified region 332.

The example of FIG. 5 is merely illustrative. In another possible arrangement, within modified region 332, data line D1 provides brightness data signals to subpixels in the second subpixel column, data line D2 provides brightness data signals to subpixels in the third subpixel column, data line D3 provides brightness data signals to subpixels in the fourth subpixel column, and data line D4 provides brightness data signals to subpixels in the fifth subpixel column. In other words, data lines D1-D4 are functional (e.g., provide data brightness signals to subpixels) within modified region 332. In contrast, data line D5 does not provide data signals to any subpixels within modified region 332 and may therefore be referred to as non-functional within modified region 332.

In general, any one of the input data lines to modified region 332 may be non-functional within modified region 332 if desired.

With the arrangement of FIG. 6, all four data lines within modified region 332 are functional for every four input data lines from normal region 334. As shown in FIG. 6, display 14 may include a first data line D1 associated with a first subpixel column in normal region 334, a second data line D2 associated with a second subpixel column in normal region 334, a third data line D3 associated with a third subpixel column in normal region 334, and a fourth data line D4 associated with a fourth subpixel column in normal region 334. Within the normal region 334, data lines D1, D2, D3, and D4 may be parallel and straight. Within modified region 332, data line D1 provides brightness data signals to subpixels in the first subpixel column, data line D2 provides brightness data signals to subpixels in the second subpixel column, data line D3 provides brightness data signals to subpixels in the third subpixel column, and data line D4 provides brightness data signals to subpixels in the fourth subpixel column. In other words, data lines D1-D4 are functional (e.g., provide data brightness signals to subpixels) within modified region 332. This pattern of functional data lines D1-D4 may be repeated across the modified region 332.

With the arrangement of FIG. 7, only four data lines within modified region 332 are functional for every six input data lines from normal region 334. As shown in FIG. 7, display 14 may include a first data line D1 associated with a first subpixel column in normal region 334, a second data line D2 associated with a second subpixel column in normal region 334, a third data line D3 associated with a third subpixel column in normal region 334, a fourth data line D4 associated with a fourth subpixel column in normal region 334, a fifth data line D5 associated with a fifth subpixel column in normal region 334, and a sixth data line D6 associated with a sixth subpixel column in normal region 334. Within the normal region 334, data lines D1, D2, D3, D4, D5, and D6 may be parallel and straight. Within modified region 332, data line D2 provides brightness data signals to subpixels in the second subpixel column, data line D3 provides brightness data signals to subpixels in the third subpixel column, data line D4 provides brightness data signals to subpixels in the fourth subpixel column, and data line D5 provides brightness data signals to subpixels in the fifth subpixel column. In other words, data lines D2, D3, D4, and D5 are functional (e.g., provide data brightness signals to subpixels) within modified region 332. In contrast, data lines D1 and D6 do not provide data signals to any subpixels within modified region 332 and may therefore be referred to as non-functional within modified region 332. Data lines D1 and D6 may also be referred to as bypass data/signal line or passthrough data/signal line for modified region 332. This pattern of functional data lines D2-D5 and non-functional data lines D1 and D6 may be repeated across the modified region 332.

The example of FIG. 7 is merely illustrative. Data lines other than data lines D1 and D6 may be the non-functional data lines if desired.

With the arrangement of FIG. 8, all four data lines within modified region 332 are functional for every four input data lines from normal region 334 (similar to as shown and described in connection with FIG. 6).

To maximize the size and/or transparency of non-pixel regions 104, data lines D may have one or more turns within modified region 332. As shown in FIGS. 5-7, the data lines may include multiple turns in the positive and/or negative X-directions while extending across the modified region 332 in the Y-direction. The turns in the data lines may allow for the data lines to be consolidated adjacent to the pixel islands, thus maximizing the size and/or transparency of non-pixel regions 104.

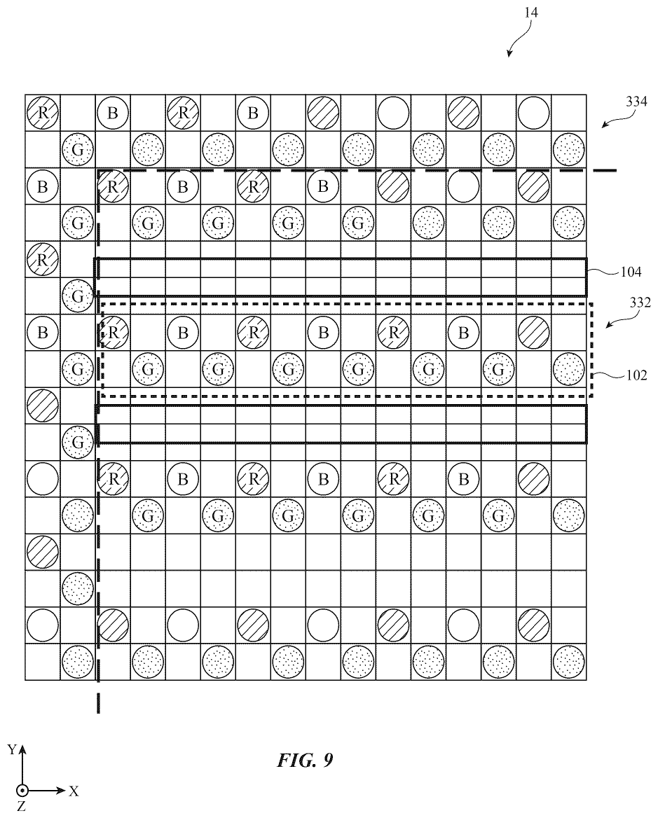

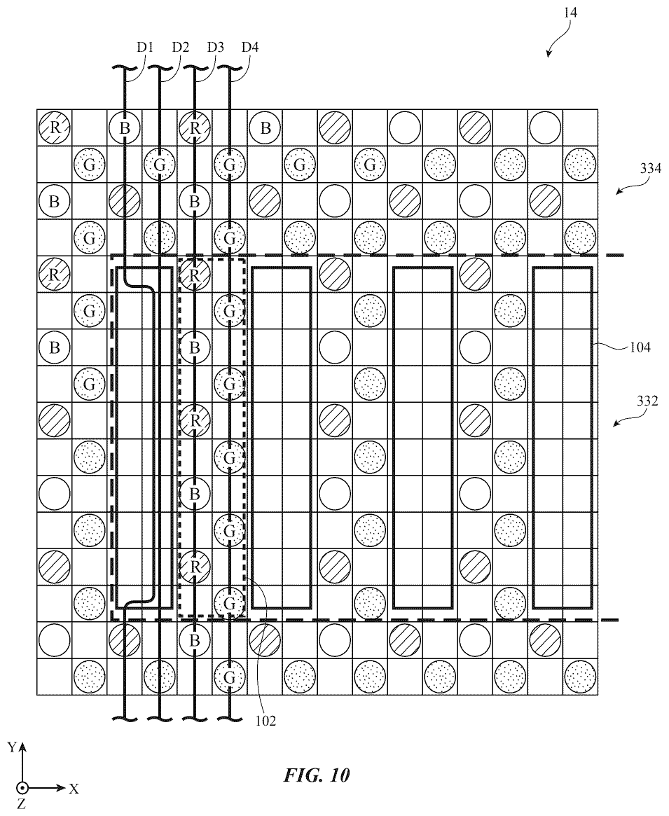

The example in FIGS. 5-8 of modified region 332 including pixel islands is merely illustrative. In an alternate arrangement, modified region 332 may include strips of pixels. FIG. 9 shows an example where modified region 332 includes horizontal strips 102 of pixels. FIG. 10 shows an example where modified region 332 includes vertical strips 102 of pixels.

In FIG. 9, every other row of pixels within normal region 334 extends continuously through modified region 332. The remaining every other row of pixels within normal region 334 is interrupted by modified region 332 and only continues on the opposing side of modified region 332. This arrangement forms horizontal pixel strips 102 within modified region 332. Each horizontal pixel strip in FIG. 9 is separated from an adjacent horizontal pixel strip by two unoccupied subpixel rows in the Y-direction.

In FIG. 10, every other column of pixels within normal region 334 extends continuously through modified region 332. The remaining every other column of pixels within normal region 334 is interrupted by modified region 332 and only continues on the opposing side of modified region 332. This arrangement forms vertical pixel strips 102 within modified region 332. Each vertical pixel strip in FIG. 10 is separated from an adjacent vertical pixel strip by two unoccupied subpixel rows in the X-direction.

With the arrangement of FIG. 9, only one gate line within modified region 332 is functional for every two input gate lines from normal region 334 (similar to as shown and described in connection with FIG. 7).

With the arrangement of FIG. 10, every gate line is functional for every input gate line from normal region 334 (similar to as in the normal region 334).

With the arrangement of FIG. 9, every data line is functional for every input data line from normal region 334 (similar to as in the normal region 334).

With the arrangement of FIG. 10, only two data lines within modified region 332 are functional for every four input data lines from normal region 334. As shown in FIG. 10, display 14 may include a first data line D1 associated with a first subpixel column in normal region 334, a second data line D2 associated with a second subpixel column in normal region 334, a third data line D3 associated with a third subpixel column in normal region 334, and a fourth data line D4 associated with a fourth subpixel column in normal region 334. Within the normal region 334, data lines D1, D2, D3, and D4 may be parallel and straight. Within modified region 332, data line D3 provides brightness data signals to subpixels in the third subpixel column and data line D4 provides brightness data signals to subpixels in the fourth subpixel column. In other words, data lines D3 and D4 are functional (e.g., provide data brightness signals to subpixels) within modified region 332. In contrast, data lines D1 and D2 do not provide data signals to any subpixels within modified region 332 and may therefore be referred to as non-functional within modified region 332. Data lines D1 and D2 may also be referred to as bypass data/signal line or passthrough data/signal line for modified region 332. This pattern of functional data lines D3 and D4 and non-functional data lines D1 and D2 may be repeated across the modified region 332.

It is noted that in each one of FIGS. 5-10, subpixels in the modified region 332 conform to regular grid 106 such that the subpixels are only included in the same size and location as in the pattern dictated by normal region 334. Said another way, the pattern of modified region 332 may be achieved exclusively by selectively removing subpixels from normal region 334. This may be advantageous to the cost and complexity of manufacturing display 14.

If care is not taken, modified display region 332 may have a different appearance from normal display region 334 when the display is turned on and/or when the display is turned off. There are many ways in which these types of visible artifacts may be mitigated.

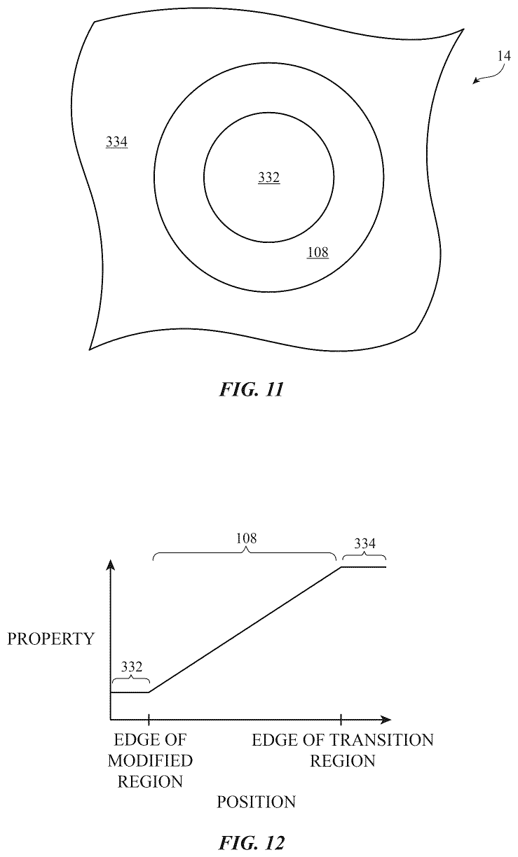

FIG. 11 shows how display 14 may include a modified region 332 having a circular footprint. This example is merely illustrative and in general the modified region may have a footprint of any desired shape. In FIG. 11, modified region 332 is formed as a patch in normal region 334 and is therefore completely laterally surrounded by normal region 334. Modified region 332 may have any of the arrangements shown in FIGS. 5-10 or any other desired arrangement with an increased transparency relative to normal region 334.

FIG. 11 shows how display 14 may include a transition region 108 between modified region 332 and normal region 334. The transition region 108 may completely laterally surround modified region 332. One or more properties may gradually change across transition region 108 as a function of distance from modified region 332.

FIG. 12 is a graph of a property as a function of position. As shown, the property may have a first magnitude in modified region 332. At the interface between modified region 332 and transition region 108, the property may begin to gradually increase. The property may gradually increase from the interface between modified region 332 and transition region 108 to the interface between transition region 108 and normal region 334. The property may have a second magnitude in normal region 332. In other words, the property gradually increases from a first magnitude to a second magnitude across the transition region.

The property may be a subpixel density or another desired property. In FIG. 4, 1 out of every 2 grid squares are occupied by a subpixel. The normal display region 334 may therefore be referred to as having a 50% subpixel density. In FIG. 5, 4 out of every 30 grid squares in modified region 332 are occupied by a subpixel. The modified display region 332 may therefore be referred to as having a 13.3% subpixel density. In this example, the subpixel density may gradually increase from 13.3% (at the modified-transition region interface) to 50% (at the transition-normal region interface) across transition region 108.

When subpixel density increases across the transition region as shown in FIG. 12, the frequency of non-pixel regions 104 may decrease across the transition region. In other words, the property of FIG. 12 may be the negative frequency of non-pixel regions 104. The non-pixel regions 104 may have approximately the same size across modified region 332 and transition region 108. At the modified-transition region interface, the frequency of non-pixel regions 104 may be at a maximum. The frequency of non-pixel regions 104 gradually decreases with increasing separation from the modified-transition region interface. The frequency of non-pixel regions 104 may decrease to 0 at the transition-normal region interface.

When subpixel density increases across the transition region as shown in FIG. 12, the size of non-pixel regions 104 may decrease across the transition region. In other words, the property of FIG. 12 may be the negative of the size of non-pixel regions 104. At the modified-transition region interface, the size (area) of non-pixel regions 104 may be at a maximum. The area of non-pixel regions 104 gradually decreases with increasing separation from the modified-transition region interface. The area of non-pixel regions 104 may decrease to 0 at the transition-normal region interface.

Varying the physical subpixel density and/or the size and/or frequency of non-pixel regions 104 through transition region 108 may mitigate a detectable border between modified region 332 and normal display region 334 even when the display is turned off.

In FIGS. 11 and 12, the physical layout of the subpixels is modified across the transition region to mitigate a detectable border between modified region 332 and normal region 334. Alternatively, the transition region 108 may have the same subpixel arrangement as normal region 334 (as shown in FIG. 4). However, varying adjustments may be applied to pixel brightnesses across the transition region to smooth the interface between normal region 334 and modified region 332.

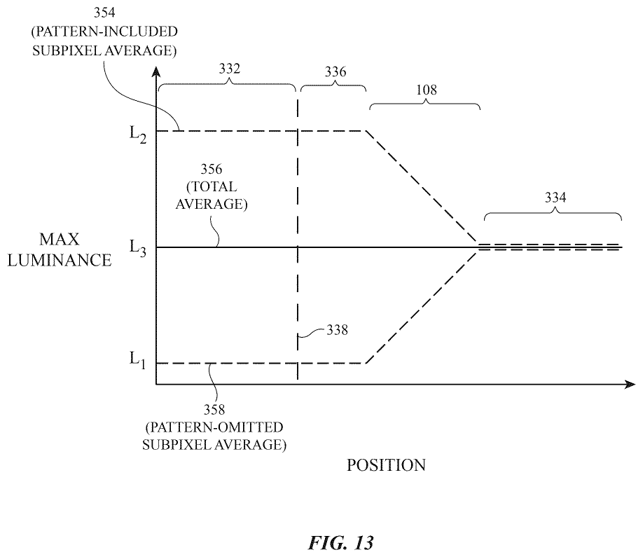

In modified region 332, the subpixels may operate with a higher maximum brightness than in normal region 334 (e.g., to achieve the same average maximum luminance in modified region 332 as in normal region 334 with less subpixels per unit area). To smooth the interface between modified region 332 and normal region 334, a portion of the display having the same physical subpixel layout as normal region 334 may be gradually dimmed and/or brightened to replicate the physical subpixel pattern of modified region 332. FIG. 13 is a graph of maximum luminance as a function of position.

To generalize, the pixels may be arranged according to a first pattern in normal region 334. In modified region 332, pixels are arranged according to a second pattern that is different than the first pattern. As previously mentioned, the second pattern may be a subset of the first pattern, meaning that subpixels from the first pattern are omitted to produce the second pattern. Subpixels that are included in both the first and second patterns may be referred to as pattern-included subpixels. Subpixels that are included in the first pattern but not the second pattern may be referred to as pattern-omitted subpixels.

Profile 354 shows the average maximum luminance of the pattern-included subpixels as a function of position within the display. Profile 358 shows the average maximum luminance of the pattern-omitted subpixels as a function of position within the display. Profile 356 shows the total average maximum luminance of both the pattern-included and pattern-omitted subpixels as a function of position within the display. It should be noted that luminance as discussed in connection with FIG. 13 may refer to the maximum luminance for the given pixels. Content displayed in real time may use luminance values that are less than the maximum luminance. However, examining maximum luminance is indicative of how the luminance transition occurs between modified region 332 and normal region 334.

Since the pattern-omitted subpixels in region 332 are removed and cannot emit light, the pattern-omitted subpixels have an average maximum luminance of L₁ (e.g., 0 or off) in modified region 332 (as shown by profile 358). The pattern-included subpixels have an average luminance of L₂ in modified region 332. The total average luminance in modified region 332 is therefore L₃ (e.g., between L₁ and L₂).

In the example of FIG. 13, display 14 includes a boundary region 336, transition region 108, and normal region 334. Each one of the boundary region 336, transition region 108, and normal region 334 may have the full pixel density pattern shown in FIG. 4. There is therefore a physical boundary 338 between a display portion having the modified arrangement of FIGS. 5-10 and a display portion having the normal arrangement of FIG. 4. However, the maximum luminance of the pixels may be modified in regions 336 and 108 to create a seamless interface between modified region 332 and normal region 334.

In normal region 334, both the pattern-included subpixels and the pattern-omitted subpixels operate with the same maximum luminance (e.g., L₃ in FIG. 13). The total average maximum luminance is therefore the same as the pattern-included subpixel average and the pattern-omitted subpixel row average in region 334.

Transition region 108 may be used to gradually transition the luminance distribution from fully one-sided (e.g., 100% of the luminance comes from pattern-included subpixels) in region 332 to fully mixed in region 334. This gradual transition in the distribution of luminance between the pattern-included subpixels and the pattern-omitted subpixels may mitigate the visibility of the boundary between the normal region 332 and modified region 334. The gradual luminance transition effectively imitates a gradual transition in physical pixel density between the reduced pixel density of region 332 and the full pixel density of region 334. For this reason, region 108 may sometimes be referred to as a pixel density transition region. However, achieving the apparent gradual transition using brightness adjustments while leaving the actual physical pixel density constant may be easier from a manufacturing perspective than creating a display with a varying physical pixel density.

As shown in FIG. 13, the average pattern-included subpixel luminance 354 gradually drops from L₂ (on a first side of the transition region closer to the boundary) to L₃ (on a second side of the transition region closer to normal region 334) across transition region 108 of the display. There may be one or more intermediate average luminance levels between L₂ and L₃. Meanwhile the average pattern-omitted subpixel luminance 358 increases from L₁ (on a first side of the transition region closer to the boundary) to L₃ (on a second side of the transition region closer to normal region 334) across transition region 108 of the display. The slope of profile 354 in region 108 may have the same magnitude but opposite sign as the slope of profile 358 in region 108. In other words, the maximum luminance of the pattern-included subpixels drops at the same rate the maximum luminance of the pattern-omitted subpixels increases. In this way, the total average luminance for the display remains the same through transition region 108, as shown by profile 356 in FIG. 13.

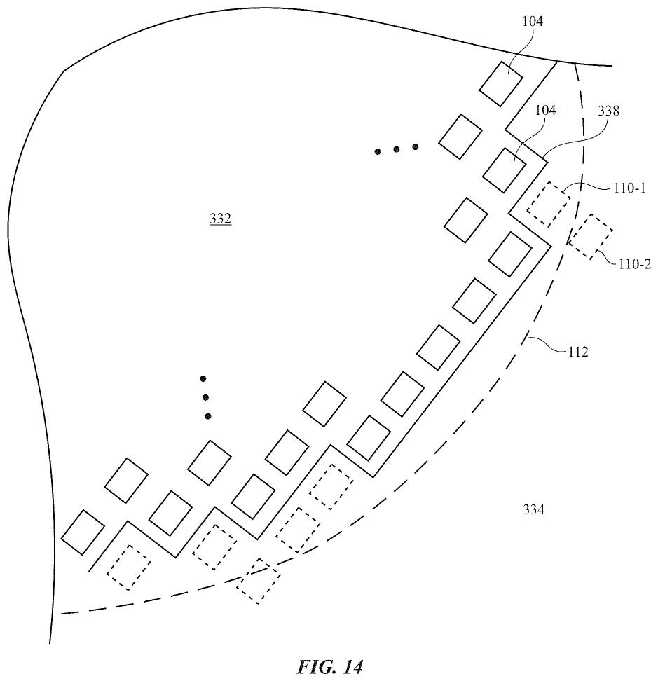

Selective dimming may also be used to smooth a boundary of modified region 332. As shown in FIG. 14, there may be a physical boundary 338 between modified region 332 and normal region 334. Modified region 334 has non-pixel regions 104 arranged in a regular pattern. The physical boundary may approximate a curve to achieve a target footprint for modified region 334. However, the physical boundary may be jagged to accommodate the regular pattern of non-pixel regions 104.

To smooth the apparent boundary of the footprint of modified region 332, pixel regions within normal display region 334 may be dimmed adjacent to physical boundary 338. FIG. 14 shows how normal display region 334 may include dimmed pixel regions 110. The positions and sizes of the dimmed pixel regions may follow the pattern of non-pixel regions 104. The dimmed pixel regions may be dimmed by varying amounts to create a perceived boundary 112 between modified region 332 and normal region 334 that has smooth curvature. The dimmed pixel regions 110 may be dimmed by decreasing amounts with increasing separation from physical boundary 338. For example, dimmed pixel region 110-1 may be dimmed by a first amount and dimmed pixel region 110-2 may be dimmed by a second amount that is less than the first amount.

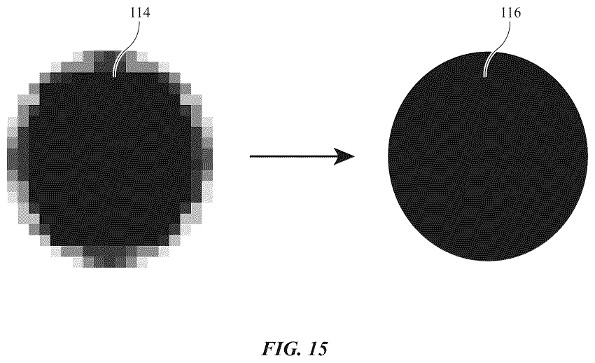

FIG. 15 shows how the selective dimming of regions 110 may create a modified region having the appearance 114 on the left side of the figure. When perceived by the human eye, this type of modified region may appear to have a smooth circular border as shown by appearance 116 on the right side of the figure. The selective dimming of FIG. 14 may therefore improve the aesthetic appearance of modified region 332 in display 14.

The modified region 332 of FIGS. 5-15 may overlap a color camera that senses red, green, and blue visible light. This example is merely illustrative and modified region 332 may instead overlap an ambient light sensor. An ambient light sensor may need less visible light for satisfactory performance than a color camera. Accordingly, when modified region 332 overlaps an ambient light sensor, the pixel layout may be the same as in normal region 334. However, modified region 332 over an ambient light sensor may include opaque masking layer and/or opaque pixel definition layer openings that allow ambient light to pass through the display to the underlying ambient light sensor.

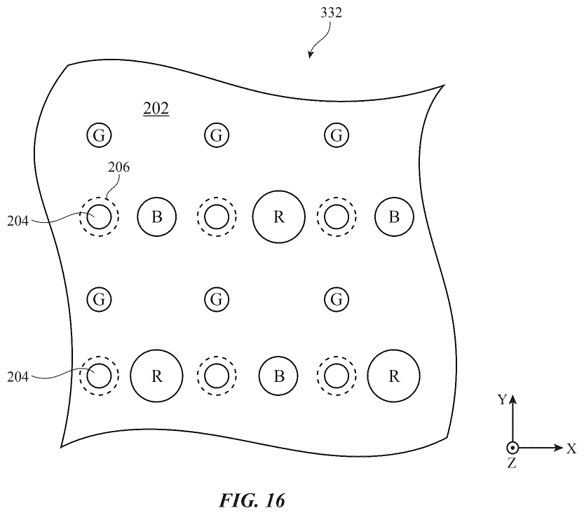

FIG. 16 is a top view of a modified display region 332 that overlaps an ambient light sensor. As shown, the modified display region includes green subpixels G, red subpixels R, and blue subpixels B in the same pattern as shown and described in connection with FIG. 4. An opaque masking layer 202 may have openings that define light-emitting apertures for each subpixel. The opaque masking layer 202 (sometimes referred to as black masking layer 202, black mask 202, etc.) may have a transparency of less than 30%, less than 20%, less than 10%, less than 5%, less than 3%, less than 1%, etc.

In the normal display region 334, opaque masking layer 202 may extend between adjacent subpixels without additional openings. However, in modified region 332 opaque masking layer 202 may include openings 204 in the regions between subpixels to allow ambient light to pass through the display to an underlying sensor. Each opening 204 may have a circular footprint (as in FIG. 16) or a footprint of any other desired shape. Each opening may have any desired diameter (e.g., between 4 and 20 microns, between 5 and 12 microns, less than 15 microns, etc.)

Display 14 may also include an opaque pixel definition layer with openings for each subpixel. In normal display region 334, the opaque pixel definition layer extends between adjacent subpixels without additional openings. The opaque pixel definition layer may, in the normal display region, define the emissive area of the subpixels. The opaque pixel definition layer may have a transparency of less than 30%, less than 20%, less than 10%, less than 5%, less than 3%, less than 1%, etc. In modified region 332 the opaque pixel definition layer may include openings 206 in the regions between subpixels to allow ambient light to pass through the display to an underlying sensor. Each opening 206 may have a circular footprint (as in FIG. 16) or a footprint of any other desired shape.

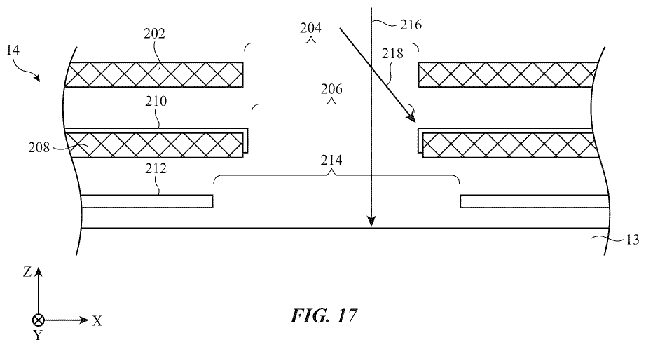

In the example of FIG. 16, opaque masking layer openings 204 are aligned with opaque pixel definition layer openings 206 in the Z-direction. The centers of openings 204 and 206 may be aligned in the Z-direction. As shown in the cross-sectional side view of FIG. 17, opaque masking layer 202 is formed over opaque pixel definition layer 208. In addition to defining light-emitting apertures for the subpixels, opaque pixel definition layer 208 supports a cathode 210. Cathode 210 may be a blanket cathode that serves as the cathode for every subpixel in display 14. The cathode may have a conductive layer with a high transparency (e.g., greater than 60%, greater than 70%, greater than 80%, greater than 90%, etc.). Cathode 210 is formed directly on the upper surface of opaque pixel definition layer 208.

FIG. 17 shows how display 14 may also include a thin-film transistor layer 212 with circuitry that is used to control the emission of light from each subpixel. Thin-film transistor layer 212 may have an opening 214 that is aligned with openings 204 and 206 to allow ambient light to pass through the display to sensor 13.

In FIGS. 16 and 17, each opaque pixel definition layer 206 is aligned in the vertical direction (e.g., in the Z-direction) with a corresponding opaque masking layer opening 204. In other words, the center of each opening 204 may be aligned with the center of a corresponding opening 206 in the Z-direction. This arrangement may allow for ambient light such as ray 216 that is parallel or close to parallel with the Z-axis to pass through to sensor 13. Light that is parallel or close to parallel with the Z-axis (e.g., the surface normal of display 14) may be referred to as on-axis light. With the arrangement of FIG. 17, however, ambient light such as ray 218 that has a steep angle relative to the Z-axis may not reach sensor 13. Light that has a steep angle relative to the Z-axis may be referred to as off-axis light.

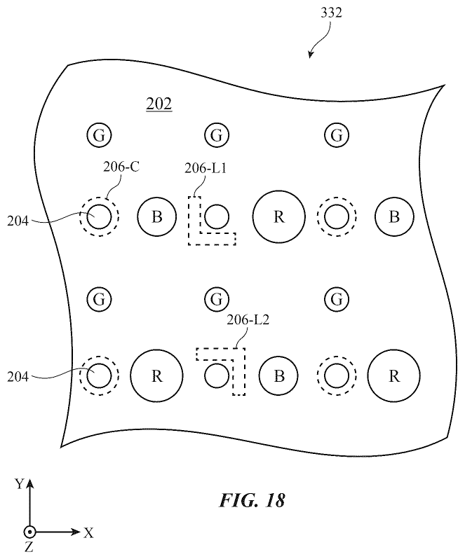

To allow a balance of both on-axis light and off-axis light to reach sensor 13, one or more opaque pixel definition layer openings 206 may have a footprint that is offset from a corresponding opaque masking layer opening 204. FIGS. 18-21 show examples of this type.

In the example of FIG. 18, opaque masking layer 202 includes openings 204 similar to as shown and described in connection with FIGS. 16 and 17. Some of openings 204 are aligned with circular opaque pixel definition layer openings 206-C, which have the same arrangement shown and described in connection with FIGS. 16 and 17. The majority of each opaque pixel definition layer opening 206-C may overlap a respective opaque masking layer opening 204 in the Z-direction. However, some of openings 204 are aligned with L-shaped opaque pixel definition layer openings 206-L.

L-shaped pixel definition layer openings 206-L have a footprint that does not overlap the footprint of the corresponding opaque masking layer opening 204. The majority of each opaque pixel definition layer opening 206-L does not overlap a respective opaque masking layer opening 204 in the Z-direction. The L-shaped opening is instead formed on two sides of a respective opening 204, allowing off-axis light from two directions to pass through to sensor 13. The L-shaped openings 206-L may include L-shaped openings 206-L1 that are adjacent to a respective opening 204 on the negative X-side and the negative Y-side of opening 204 and L-shaped openings 206-L2 that are adjacent to a respective opening 204 on the positive X-side and the positive Y-side of opening 204. L-shaped openings 206-L1 may allow off-axis light that is incident on display 14 in the negative Y-direction and the negative X-direction to reach sensor 13. L-shaped openings 206-L2 may allow off-axis light that is incident on display 14 in the positive Y-direction and the positive X-direction to reach sensor 13. Including both types of L-shaped openings therefore allows off-axis light from all directions to reach sensor 13.

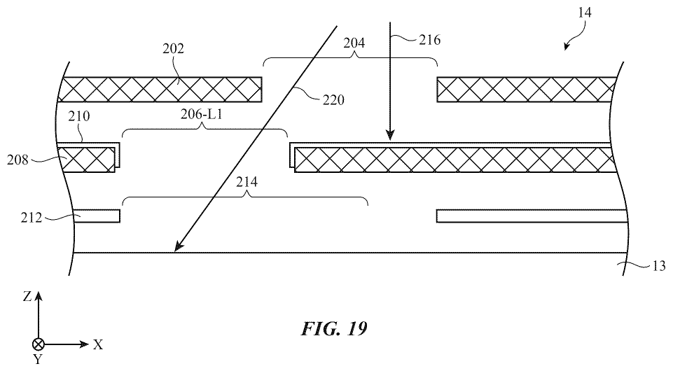

FIG. 19 shows a cross-sectional side view of an L-shaped opening 206-L. As shown, the offset between openings 204 and 206-L1 blocks on-axis light 216 but allows off-axis light 220 to pass through to sensor 13.

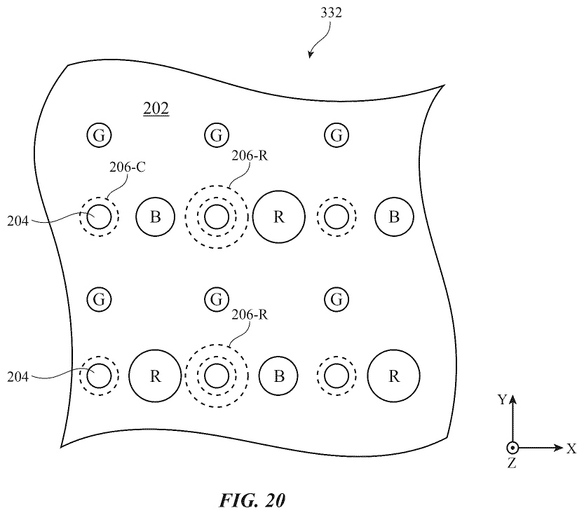

In the example of FIG. 20, opaque masking layer 202 includes openings 204 similar to as shown and described in connection with FIGS. 16 and 17. Some of openings 204 are aligned with circular opaque pixel definition layer openings 206-C, which have the same arrangement shown and described in connection with FIGS. 16 and 17. The majority of each opaque pixel definition layer opening 206-C may overlap a respective opaque masking layer opening 204 in the Z-direction. However, some of openings 204 are aligned with ring-shaped opaque pixel definition layer openings 206-R.

Ring-shaped pixel definition layer openings 206-R have a footprint that does not overlap the footprint of the corresponding opaque masking layer opening 204. The majority of each opaque pixel definition layer opening 206-R does not overlap a respective opaque masking layer opening 204 in the Z-direction. The ring-shaped opening is instead formed in a ring around a respective opening 204, allowing off-axis light from all off-axis directions to pass through to sensor 13.

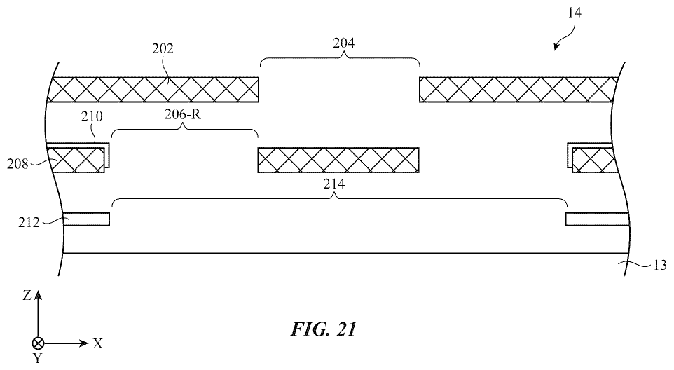

FIG. 21 shows a cross-sectional side view of a ring-shaped opening 206-R. As shown, a portion of opaque pixel definition layer 208 is laterally surrounded by the ring-shaped opening 206-R. The remaining portion of the opaque pixel definition layer 208 may be aligned with opening 204 in the Z-direction.

FIGS. 17, 19, and 21 show how cathode 210 may be selectively removed within the footprint of opaque pixel definition layer opening 206. The cathode 210 may be completely removed in this area or may be partially removed in this area. Removing the cathode in opaque pixel definition layer opening 206 may increase transmission through the opening.

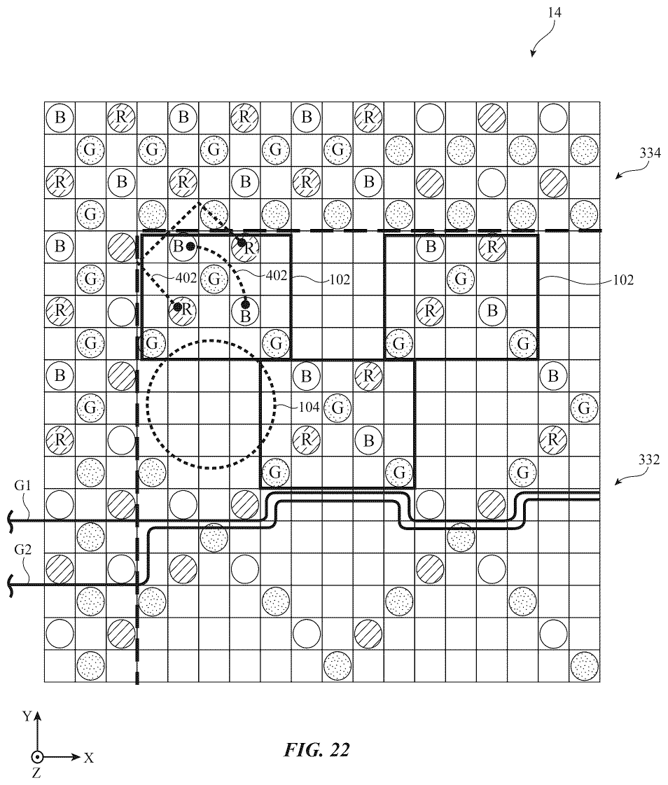

FIGS. 22-25 show additional arrangements for modified display region 332 in display 14. In FIG. 22, modified display region 332 may include a plurality of pixel regions 102 (sometimes referred to as subpixel groups, subpixel regions, etc.) as well as non-pixel regions 104 (sometimes referred to as windows, transparent regions, etc.).

In FIG. 22, each pixel group 102 includes four rows of subpixels and five columns of subpixels. The first row of subpixels includes a blue subpixel in the second column and a red subpixel in the fourth column. The second row of subpixels includes a green subpixel in the third column. The third row of subpixels includes a red subpixel in the second column and a blue subpixel in the fourth column. The fourth row of subpixels includes a green subpixel in the first column and a green subpixel in the fifth column.

In the displays described herein, each display pixel 22 may include both a thin-film transistor layer and an emissive layer. Each emissive layer portion may have associated circuitry on the thin-film transistor layer that controls the magnitude of light emitted from that emissive layer portion. Both the emissive layer and thin-film transistor layer may have corresponding subpixels within the pixel. Each subpixel may be associated with a different color of light (e.g., red, green, and blue). The emissive layer portion for a given subpixel does not necessarily need to have the same footprint as its associated thin-film transistor layer portion. Hereinafter, the term subpixel may sometimes be used to refer to the combination of an emissive layer portion and a thin-film transistor layer portion. Additionally, the thin-film transistor layer may be referred to as having thin-film transistor subpixels (e.g., a portion of the thin-film transistor layer that controls a respective emissive area, sometimes referred to as thin-film transistor layer pixels, thin-film transistor layer subpixels or simply subpixels) and the emissive layer may be referred to as having emissive layer subpixels (sometimes referred to as emissive pixels, emissive subpixels or simply subpixels).

Different arrangements may be used for the thin-film transistor subpixels and the emissive subpixels. The red subpixels R, blue subpixels B, and green subpixels G shown and described herein may correspond to emissive subpixels. Each emissive subpixel therefore occupies one grid square of the grid of FIG. 22. The thin-film transistor subpixels, meanwhile, may occupy two grid squares of the grid of FIG. 22. In normal display region 334, each emissive subpixel occupies one grid square and overlaps a corresponding thin-film transistor subpixel that controls that emissive subpixel and that occupies two grid squares. The thin-film transistor subpixels in modified region 332 may also each occupy two grid squares. However, the thin-film transistor subpixels need not follow the pattern of the emissive subpixels in the pixel group 102.

In order to increase the transmission of light through modified region 332 without reducing the light-emitting area of the display in modified region 332, additional thin-film transistor subpixels may be removed from modified region 332. For example, a thin-film transistor subpixel in pixel group 102 may control the light emitted from two or more emissive sub-pixels (e.g., that are shorted together). This reduces the number of thin-film transistor subpixels required in modified display region 332.

Consider the example of FIG. 22. Each pixel group 102 includes seven emissive subpixels. If each emissive subpixel has a corresponding thin-film transistor subpixel, each pixel group 102 will have seven thin-film transistor subpixels. Alternatively, as shown in FIG. 22, at least some emissive subpixels of the same color may be shorted together.

FIG. 22 shows an example where the two blue emissive subpixels in pixel group 102 are shorted together by a corresponding shorting path 402. Accordingly, one thin-film transistor subpixel may control the emission of light from the two blue emissive subpixels in pixel group 102. Additionally, the two red emissive subpixels in pixel group 102 are shorted together by a corresponding shorting path 402. Accordingly, one thin-film transistor subpixel may control the emission of light from the two red emissive subpixels in pixel group 102.

In the example of FIG. 22, each green emissive subpixel has a corresponding thin-film transistor subpixel. There are therefore three thin-film transistor subpixels that control the three green emissive subpixels. In total, the repeating pixel group 102 of FIG. 22 has five thin-film transistor subpixels that control seven emissive subpixels. The five thin-film transistor subpixels may occupy any desired grid squares of the four rows and five columns of grid squares in pixel group 102. As one example, the five thin-film transistor subpixels occupy the top two rows of all five columns of each pixel group.

In FIG. 22, the pixel groups are arranged in a checkerboard pattern. In FIG. 22, adjacent pixel groups within a common row of pixel groups are separated by three grid squares that are unoccupied by any subpixels. Adjacent pixel groups within a common column of pixel islands are separated by four grid squares that are unoccupied by any subpixels. Consequently, there are no entirely unoccupied columns of grid squares between adjacent columns of pixel groups in region 332 and no entirely unoccupied rows of grid squares between adjacent rows of pixel groups in region 332.

With the arrangement of FIG. 22, only one gate line within modified region 332 is functional for every two input gate lines from normal region 334. As shown in FIG. 22, display 14 may include a first gate line G1 associated with a first pixel row in normal region 334 and a second gate line G2 associated with a second pixel row in normal region 334. Within the normal region 334, gate lines G1 and G2 may be parallel and straight. Within modified region 332, gate line G1 provides gate signals to subpixels in a first row of pixel islands. In other words, gate line G1 is functional (e.g., provide gate signals to subpixels) within modified region 332. In contrast, gate line G2 does not provide gate signals to any subpixels within modified region 332 and may therefore be referred to as non-functional within modified region 332. Gate line G2 may also be referred to as a bypass gate/signal line or passthrough gate/signal line for modified region 332. This pattern of functional gate lines G1 alternating with non-functional gate lines G2 may be repeated across the modified region 332. The functional gate lines may be the odd numbered gate lines (e.g., G1, G3, G5, etc.) or the even numbered gate lines (e.g., G2, G4, G6, etc.).

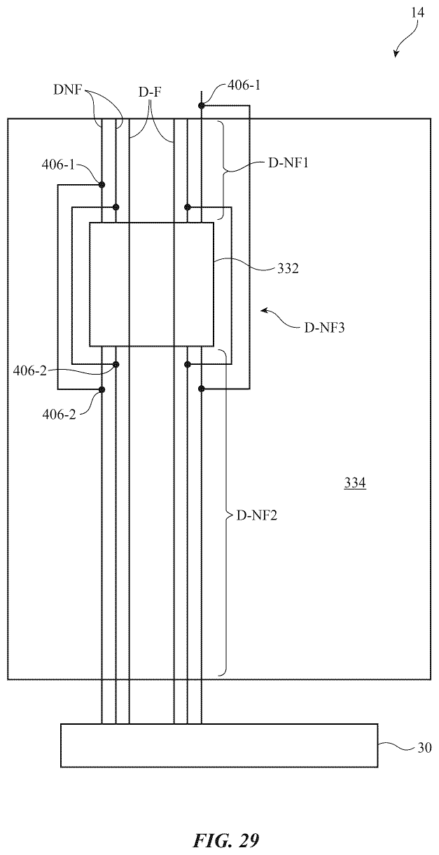

The example in FIG. 22 of gate line G2 extending through modified region 332 is merely illustrative. If desired, the non-functional gate lines may be routed around the modified region (as will be shown and discussed in greater detail in connection with FIG. 29).

To maximize the size and/or transparency of non-pixel regions 104, gate lines G in FIG. 22 may have one or more turns within modified region 332. As shown in FIG. 22, the gate lines may include multiple turns (sometimes referred to as curves, bends, etc.) in the positive and/or negative Y-directions while extending across the modified region 332 in the X-direction. The turns in the gate lines may allow for the gate lines to be consolidated adjacent to the pixel groups, thus maximizing the size and/or transparency of non-pixel regions 104.

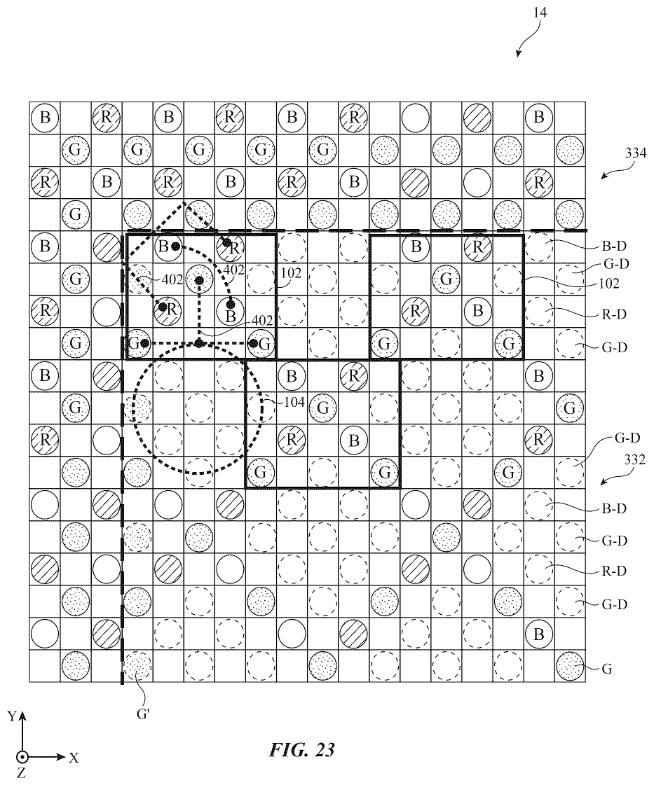

The example of FIG. 22 is merely illustrative. In another possible arrangement, shown in FIG. 23, the three green emissive subpixels in pixel group 102 are shorted together by a corresponding shorting path 402. Accordingly, one thin-film transistor subpixel may control the emission of light from the three green emissive subpixels in pixel group 102. In total, the repeating pixel group 102 of FIG. 23 has three thin-film transistor subpixels that control seven emissive subpixels. The three thin-film transistor subpixels may occupy any desired grid squares of the four rows and five columns of grid squares in pixel group 102. As one example, the three thin-film transistor subpixels occupy the top two rows of the second, third, and fourth columns of each pixel group.

In FIG. 23, the pixel groups are arranged in a checkerboard pattern. In FIG. 23, adjacent pixel groups within a common row of pixel groups are separated by three grid squares that are unoccupied by any subpixels. Adjacent pixel groups within a common column of pixel islands are separated by four grid squares that are unoccupied by any subpixels. Consequently, there are no entirely unoccupied columns of grid squares between adjacent columns of pixel groups in region 332 and no entirely unoccupied rows of grid squares between adjacent rows of pixel groups in region 332.

With the arrangement of FIG. 23, only one gate line within modified region 332 is functional for every two input gate lines from normal region 334 (similar to as shown and described in connection with FIG. 22). The functional gate lines may be the odd numbered gate lines (e.g., G1, G3, G5, etc.) or the even numbered gate lines (e.g., G2, G4, G6, etc.).

If desired, region 332 may optionally include additional pixels at the boundary between normal region 334 and modified region 332. FIG. 23 shows how additional green subpixels G′ may optionally be included at the column adjacent to the border between normal region 334 and modified region 332. The column adjacent to the border between normal region 334 and modified region 332 therefore has the same pattern of green subpixels as in normal region 334. Four additional green subpixels G′ are shown in FIG. 23. FIG. 23 shows the column on the left-most side of modified region 332. However, it should be understood that the column on the right-most side of modified region 332 may include additional pixels at the boundary between normal region 334 and modified region 332. Similarly, the rows at the top and bottom sides of modified region 332 may include additional pixels at the boundary between normal region 334 and modified region 332. Including the additional pixels at the boundary between normal region 334 and modified region 332 may mitigate the visibility of a border between normal region 334 and modified region 332.

FIG. 23 further shows how one or more dummy subpixels may optionally be included in modified region 332. The dummy subpixels do not emit light and therefore may be referred to as non-functional. The presence of the dummy subpixels may mitigate the visibility of modified region 332 when display 14 is turned off. The dummy subpixels may include green dummy subpixels G-D that include green OLED layers (e.g., the same emissive layers as the green subpixels G), red dummy subpixels R-D that include red OLED layers (e.g., the same emissive layers as the red subpixels G), and/or blue dummy subpixels B-D that include blue OLED layers (e.g., the same emissive layers as the blue subpixels B).

The dummy subpixels may be arranged according to the pattern of the normal display region 334. Consider columns of pixels that extend through modified region 332. Within normal region 334, a first subset of these columns has green emissive subpixels. Within modified region 332, the first subset of these columns has green emissive subpixels and green dummy subpixels. Consider the column on the far right of FIG. 23. The grid squares within this column alternate between empty grid squares and grid squares with green subpixels (e.g., green emissive subpixels or green dummy subpixels G-D).

Within normal region 334, a second subset of these columns has alternating blue and red emissive subpixels. Within modified region 334, the second subset of these columns has red emissive subpixels, red dummy subpixels, blue emissive subpixels, and blue dummy subpixels. Consider the column second-from-right of FIG. 23. The grid squares within this column alternate between empty grid squares and grid squares with red subpixels (e.g., red emissive subpixels R or red dummy subpixels R-D) or blue subpixels (e.g., blue emissive subpixels B or blue dummy subpixels B-D).

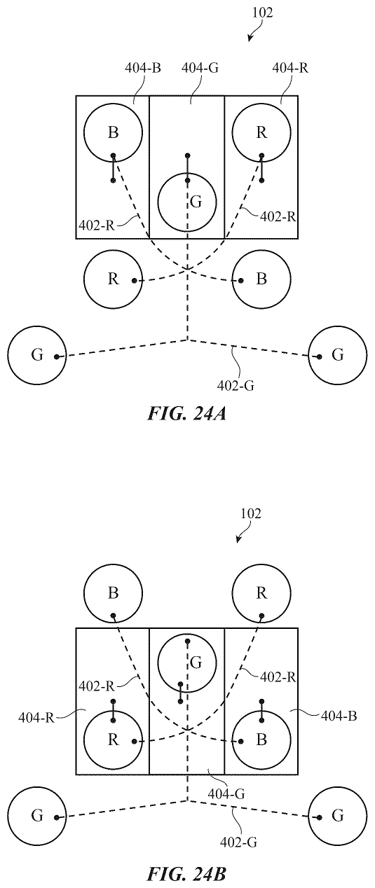

FIG. 24A is a top view of a pixel group 102 from FIG. 23. FIG. 24A shows the relative position of thin-film transistor subpixels for the pixel group. A first thin-film transistor subpixel 404-B is used to control two emissive subpixels B. The emissive subpixels B are shorted together (e.g., the anodes of the two emissive subpixels are shorted together) using respective shorting path 402-B. A second thin-film transistor subpixel 404-G is used to control three emissive subpixels G. The emissive subpixels G are shorted together using respective shorting path 402-G. A third thin-film transistor subpixel 404-R is used to control two emissive subpixels R. The emissive subpixels R are shorted together using respective shorting path 402-R.

Shorting paths 402 may be formed by conductive routing lines on one or more layers within the display (e.g., within the thin-film transistor circuitry layer in the display). Each shorting path may electrically connect the first anode of a first emissive sub-pixel to the second anode of a second emissive sub-pixel. In this way, when a thin-film transistor sub-pixel applies a drive voltage to the first anode, the drive voltage is also applied to the second anode. Both the first and second emissive sub-pixels therefore emit approximately the same amount of light. This partially reduces the effective resolution of the display in the pixel removal region (since the shorted pixels necessarily emit the same amount of light). However, the display may still have a satisfactory appearance to the viewer in modified region 332 even with the shorted emissive sub-pixels.

The arrangement of pixel group 102 in FIG. 24A is merely illustrative. FIG. 24B shows another possible arrangement where the left-most thin-film transistor subpixel is thin-film transistor subpixel 404-R (which is used to control two emissive subpixels R), the middle thin-film transistor subpixel is thin-film transistor subpixel 404-G (which is used to control three emissive subpixels G), and the right-most thin-film transistor subpixel is thin-film transistor subpixel 404-B (which is used to control two emissive subpixels B).

In FIG. 24A, a top half of thin-film transistor 404-B overlaps a blue emissive subpixel B, a bottom half of thin-film transistor 404-G overlaps a green emissive subpixel G, and a top half of thin-film transistor 404-R overlaps a red emissive subpixel R. In FIG. 24B, a bottom half of thin-film transistor 404-R overlaps a red emissive subpixel R, a top half of thin-film transistor 404-G overlaps a green emissive subpixel G, and a bottom half of thin-film transistor 404-B overlaps a blue emissive subpixel B. Said another way, in FIG. 24A the thin-film transistors occupy rows 1 and 2 and columns 2 through 4 of the grid squares of pixel group 102. In FIG. 24B the thin-film transistors occupy rows 2 and 3 and columns 2 through 4 of the grid squares of pixel group 102.

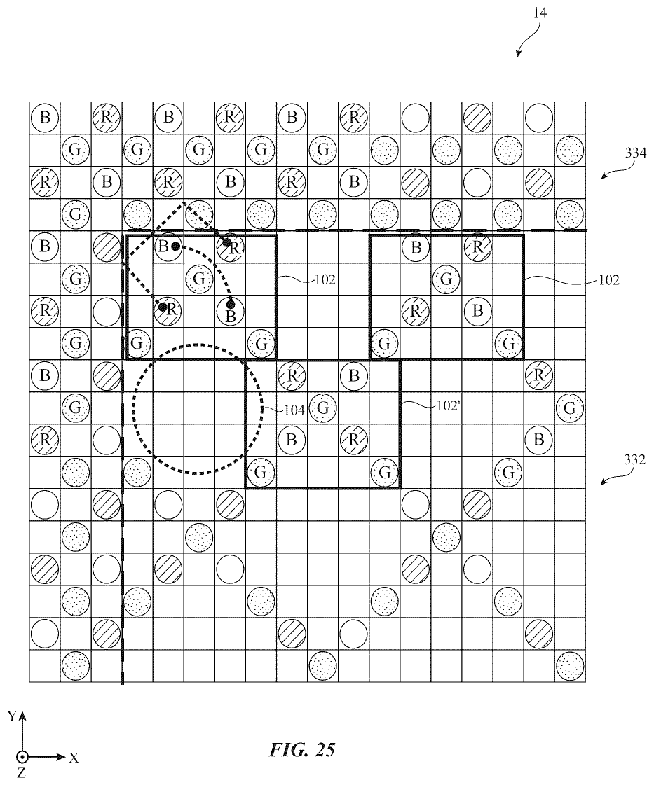

In the example of FIGS. 22 and 23, pixel group 102 is repeated across modified display region 332. The same pixel group is repeated without modification in FIGS. 22 and 23. This example is merely illustrative. In another possible arrangement, shown in FIG. 25, each pixel group 102 has the same arrangement as described in connection with FIG. 22. However, the modified pixel region includes pixel groups 102′ in addition to pixel group 102.

In FIG. 25, each pixel group 102′ includes four rows of subpixels and five columns of subpixels. The first row of subpixels includes a red subpixel in the second column and a blue subpixel in the fourth column. The second row of subpixels includes a green subpixel in the third column. The third row of subpixels includes a blue subpixel in the second column and a red subpixel in the fourth column. The fourth row of subpixels includes a green subpixel in the first column and a green subpixel in the fifth column.

In other words, pixel groups 102 and 102′ both include the same total layout of grid squares (e.g., four rows and five columns). Additionally, the occupied grid squares within the pixel groups are the same for pixel groups 102 and 102′ (e.g., columns 2 and 4 of row, 1, column 3 of row 2, columns 2 and 4 of row 3, and columns 1 and 5 of row 4). However the red and blue subpixels are swapped in pixel group 102′ relative to pixel group 102.

Every other row of pixel groups may be a pixel group 102. Every other row of pixel groups may be a pixel group 102′ with swapped red and blue subpixels relative to pixel group 102. Said another way, rows of pixel groups 102 alternate with rows of pixel groups 102′ in the checkerboard layout of pixel groups. This type of arrangement may mitigate artifacts that may otherwise be present in the display of FIG. 22.

In FIG. 25, the pixel groups are arranged in a checkerboard pattern. Adjacent pixel groups within a common row of pixel groups are separated by three grid squares that are unoccupied by any subpixels. Adjacent pixel groups within a common column of pixel islands are separated by four grid squares that are unoccupied by any subpixels. Consequently, there are no entirely unoccupied columns of grid squares between adjacent columns of pixel groups in region 332 and no entirely unoccupied rows of grid squares between adjacent rows of pixel groups in region 332.

With the arrangement of FIG. 25, only one gate line within modified region 332 is functional for every two input gate lines from normal region 334 (similar to as shown and described in connection with FIG. 22).

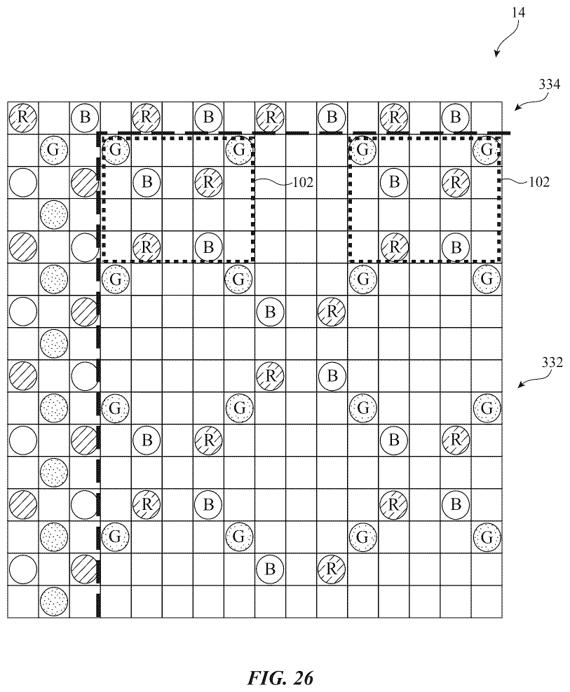

FIG. 26 shows another possible arrangement for pixel group 102. In the example of FIG. 26, each pixel group 102 includes four rows of grid squares and five columns of grid squares. The first row of grid squares includes a green emissive subpixel in the first column and a green emissive subpixel in the fifth column. The second row of grid squares includes a blue emissive subpixel in the second column and a red emissive subpixel in the fourth column. The third row of grid squares does not include any emissive subpixels. The fourth row of grid squares includes a red emissive subpixel in the second column and a blue emissive subpixel in the fourth column.

In FIG. 26, the pixel groups are arranged in a checkerboard pattern. Adjacent pixel groups within a common row of pixel groups are separated by three grid squares that are unoccupied by any subpixels. Adjacent pixel groups within a common column of pixel islands are separated by four grid squares that are unoccupied by any subpixels. Consequently, there are no entirely unoccupied columns of grid squares between adjacent columns of pixel groups in region 332 and no entirely unoccupied rows of grid squares between adjacent rows of pixel groups in region 332.

In FIG. 26, one or more emissive subpixels may be shorted together similar to as shown in FIGS. 22-25. In one example, the two blue emissive subpixels in pixel group 102 may be shorted together by a corresponding shorting path and share a single thin-film transistor subpixel, the two red emissive subpixels in pixel group 102 may be shorted together by a corresponding shorting path and share a single thin-film transistor subpixel, and each green emissive subpixel may have a respective thin-film transistor subpixel. With this arrangement, there are four thin-film transistor subpixels and six emissive subpixels in each pixel group 102 in FIG. 26.

In another example, the two blue emissive subpixels in pixel group 102 may be shorted together by a corresponding shorting path and share a single thin-film transistor subpixel, the two red emissive subpixels in pixel group 102 may be shorted together by a corresponding shorting path and share a single thin-film transistor subpixel, and the two green emissive subpixels in pixel group 102 may be shorted together by a corresponding shorting path and share a single thin-film transistor subpixel. With this arrangement, there are three thin-film transistor subpixels and six emissive subpixels in each pixel group 102 in FIG. 26.

With the arrangement of FIG. 26, only one gate line within modified region 332 is functional for every two input gate lines from normal region 334 (similar to as shown and described in connection with FIG. 22).

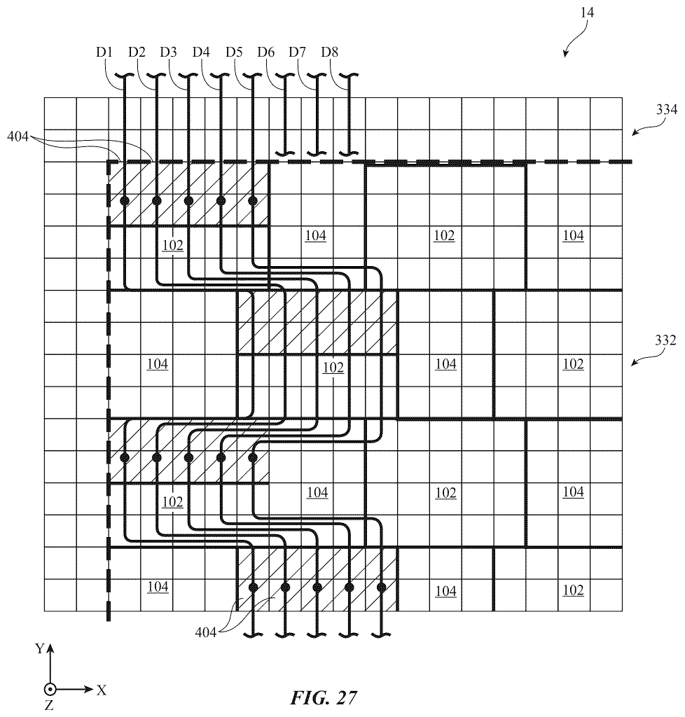

In the arrangement of FIG. 22, only five data lines within modified region 332 are functional for every eight input data lines from normal region 334. FIG. 27 shows a data line arrangement for a display of the type of FIG. 22. As shown in FIG. 27, display 14 may include a first data line D1 associated with a first subpixel column in normal region 334, a second data line D2 associated with a second subpixel column in normal region 334, a third data line D3 associated with a third subpixel column in normal region 334, a fourth data line D4 associated with a fourth subpixel column in normal region 334, a fifth data line D5 associated with a fifth subpixel column in normal region 334, a sixth data line D6 associated with a sixth subpixel column in normal region 334, a seventh data line D7 associated with a seventh subpixel column in normal region 334, and an eighth data line D8 associated with an eighth subpixel column in normal region 334.

FIG. 27 shows pixel groups 102 that alternate with transparent windows 104 in a checkerboard pattern. In the example of FIG. 27, each pixel group 102 includes five thin-film transistor pixels 404.

Within the normal region 334, data lines D1-D8 may be parallel and straight. Within modified region 332, data line D1 provides brightness data signals to the thin-film transistor subpixel 404 in the first column of grid squares for each pixel group, data line D2 provides brightness data signals to the thin-film transistor subpixel 404 in the second column of grid squares for each pixel group, data line D3 provides brightness data signals to the thin-film transistor subpixel 404 in the third column of grid squares for each pixel group, data line D4 provides brightness data signals to the thin-film transistor subpixel 404 in the fourth column of grid squares for each pixel group, and data line D5 provides brightness data signals to the thin-film transistor subpixel 404 in the fifth column of grid squares for each pixel group. In other words, data lines D1-D5 are functional (e.g., provide data brightness signals to thin-film transistor subpixels) within modified region 332. In contrast, data lines D6-D8 do not provide data signals to any subpixels within modified region 332 and may therefore be referred to as non-functional within modified region 332. Data lines D6-D8 may also be referred to as a bypass data/signal line or passthrough data/signal line for modified region 332. This pattern of functional data lines D1-D5 and non-functional data lines D6-D8 may be repeated across the modified region 332.

The example of FIG. 27 is merely illustrative. In another possible arrangement, all of data lines D1-D8 may be functional data lines and there may be no bypass data lines.

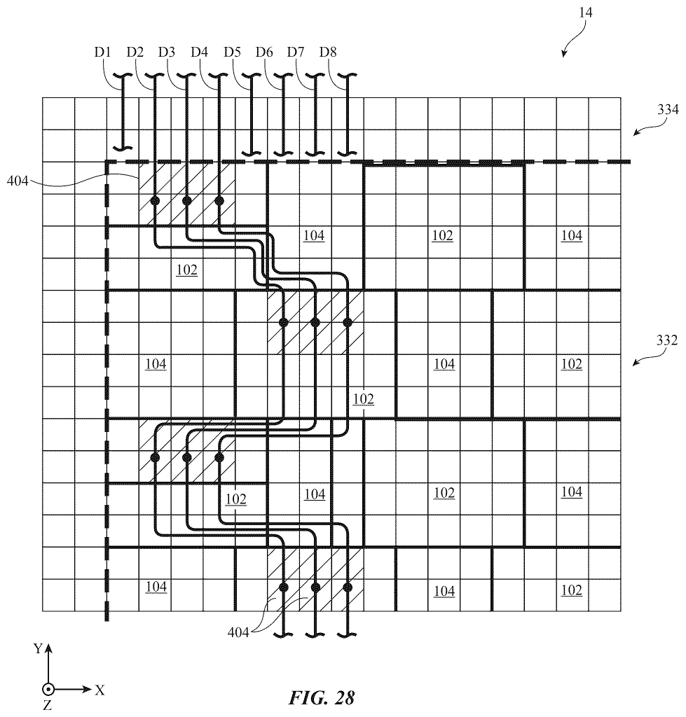

In the arrangement of FIG. 23, only three data lines within modified region 332 are functional for every eight input data lines from normal region 334. FIG. 28 shows a data line arrangement for a display of the type of FIG. 23. As shown in FIG. 28, display 14 may include a first data line D1 associated with a first subpixel column in normal region 334, a second data line D2 associated with a second subpixel column in normal region 334, a third data line D3 associated with a third subpixel column in normal region 334, a fourth data line D4 associated with a fourth subpixel column in normal region 334, a fifth data line D5 associated with a fifth subpixel column in normal region 334, a sixth data line D6 associated with a sixth subpixel column in normal region 334, a seventh data line D7 associated with a seventh subpixel column in normal region 334, and an eighth data line D8 associated with an eighth subpixel column in normal region 334.

FIG. 28 shows pixel groups 102 that alternate with transparent windows 104 in a checkerboard pattern. In the example of FIG. 28, each pixel group 102 includes three thin-film transistor pixels 404.

Within the normal region 334, data lines D1-D8 may be parallel and straight. Within modified region 332, data line D2 provides brightness data signals to the thin-film transistor subpixel 404 in the second column of grid squares for each pixel group, data line D3 provides brightness data signals to the thin-film transistor subpixel 404 in the third column of grid squares for each pixel group, and data line D4 provides brightness data signals to the thin-film transistor subpixel 404 in the fourth column of grid squares for each pixel group. In other words, data lines D2-D4 are functional (e.g., provide data brightness signals to thin-film transistor subpixels) within modified region 332. In contrast, data lines D1 and D5-D8 do not provide data signals to any subpixels within modified region 332 and may therefore be referred to as non-functional within modified region 332. Data lines D1 and D5-D8 may also be referred to as a bypass data/signal line or passthrough data/signal line for modified region 332. This pattern of functional data lines D2-D4 and non-functional data lines D1 and D5-D8 may be repeated across the modified region 332.

To maximize the size and/or transparency of non-pixel regions 104, data lines D in FIGS. 27 and 28 may have one or more turns within modified region 332. As shown in FIGS. 27 and 28, the data lines may include multiple turns in the positive and/or negative X-directions while extending across the modified region 332 in the Y-direction. The turns in the data lines may allow for the data lines to be consolidated adjacent to the pixel groups, thus maximizing the size and/or transparency of non-pixel regions 104.

The non-functional data lines (e.g., D6-D8 in FIG. 27 and D1 and D5-D8 in FIG. 28) may optionally be routed through modified region 332 (with one or more turns if desired). FIGS. 5 and 7 show examples of routing non-functional data lines through the modified region.

Routing non-functional data lines through the modified region may mitigate transparency in the modified region. To increase transparency in the modified region, the non-functional data lines may instead be routed around the modified region without entering the modified region. FIG. 29 is a top view of a display showing an arrangement of this type.

FIG. 29 shows a modified display region 332 and a normal display region 334. FIG. 29 shows how data lines may be connected to display driver circuitry 30. The data lines may include a plurality of data lines that are aligned with modified region 332. The data lines aligned with modified region 332 include functional data lines D-F that are used to provide brightness signals to subpixels in the modified region and non-functional data lines D-NF that are not used to provide brightness signals to any subpixels in the modified region. It should be understood that both data lines D-F and D-NF provide brightness signals to subpixels in normal display region 334.

In the example of FIG. 29, each non-functional data line D-NF includes a first portion D-NF1 on a first side of modified display region 332, a second portion D-NF2 on a second side of modified display region 332, and a supplemental portion D-NF3 that is routed around the modified display region to electrically connect portions D-NF1 and D-NF2. Supplemental portion D-NF3 does not provide brightness signals to any subpixels in normal display region 334 (even though D-NF3 is routed through normal region 334).

The supplemental portion D-NF3 is electrically connected to portion D-NF1 at electrical connection 406-1. The supplemental portion D-NF3 is electrically connected to portion D-NF2 at electrical connection 406-2. The active area of the display may be surrounded by an inactive area (sometimes referred to as non-light-emitting area). For each data line, each one of electrical connections 406-1 and 406-2 may be positioned within the active area AA or in the inactive area IA. In the example of FIG. 29, the electrical connections 406-2 are all within the active area of the display. The leftmost three of the electrical connections 406-1 in FIG. 29 are within the active area of the display. The rightmost of the electrical connections 406-1 in FIG. 29 is within the inactive area of the display.

Data lines that do not provide brightness signals to any subpixels in modified display region 332 may therefore be routed around the modified display region as shown in FIG. 29. These techniques may also be used to route gate lines that do not provide signals to any subpixels in modified display region 332 around the modified display region.

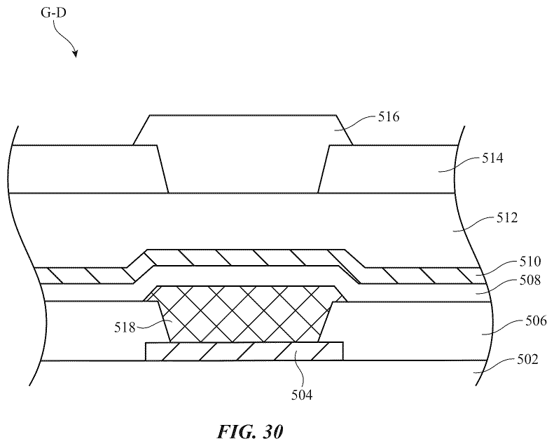

Any of the displays described herein may optionally include dummy subpixels as described in connection with FIG. 23. FIG. 30 is a cross-sectional side view of an illustrative green dummy subpixel. As shown in FIG. 30, green dummy subpixel G-D may include a conductive electrode (anode) 504 formed on substrate 502. A pixel definition layer 506 may define an aperture through which the anode is exposed. OLED layers 508 are formed over anode 504. The OLED layers 508 may include a hole injection layer, a hole transport layer, an emissive layer (e.g., a green emissive layer), an electron transport layer, an electronic injection layer, an electron blocking layer, a charge generation layer, and/or a hole blocking layer. In the dummy subpixel, the emissive layer may optionally be omitted. A common electrode (cathode) 510 is formed over the array of pixels. The cathode may be formed as a blanket layer across the entire array and serves as the cathode electrode for each subpixel (both functional and non-functional) in the display. The OLED layers 508 are interposed between the cathode 510 and respective anodes 504.

Dummy subpixel G-D may also include one or more encapsulation layers 512 over cathode 510. A black matrix layer 514 is formed over the one or more encapsulation layers. The black matrix layer 514 defines an opening for a green color filter element 516. Finally, the dummy subpixel G-D may include a spacer 518 between anode 504 and OLED layers 508. The spacer may prevent current from passing through OLED layers 508 and generating light.

The example of a green dummy subpixel in FIG. 30 is merely illustrative. Blue and red dummy subpixels may have the same arrangement as in FIG. 30 (with red and blue color filter elements and OLED layers, respectively).

The emissive subpixels in display 14 may have the same arrangement as the dummy subpixel in FIG. 30 except for the spacer 518 is omitted in the emissive subpixels. By matching the structure of the dummy subpixels to the emissive subpixels as closely as possible, the off-state optical properties (e.g., reflectance) of the dummy subpixels will desirably match those of the emissive subpixels. Cathode 510 may be electrically connected to a power supply voltage ELVSS. For the dummy pixels of FIG. 30, the anode 504 may be electrically connected to any direct current to prevent the anode from electrically floating. In the emissive subpixels, spacer 518 is omitted and anode 504 is electrically connected to a voltage that controls the magnitude of current across emissive layers 508 (and therefore the brightness of the emissive subpixel). In an alternate dummy subpixel arrangement, spacer 518 may be omitted and the anode 504 may be electrically connected to a voltage that is no more positive than ELVSS (e.g., more negative than ELVSS) to prevent leakage. In yet another possible dummy subpixel arrangement, spacer 518 may be omitted and there may be no opening in pixel definition layer 506 over anode 504 (such that the pixel definition layer with a planar upper surface serves as a spacer between the anode 504 and OLED layers 508).

It is noted that the circular footprint of the emissive subpixels shown herein is merely illustrative. In general, emissive subpixels may have footprints of any desired shapes.

The foregoing is merely illustrative and various modifications can be made by those skilled in the art without departing from the scope and spirit of the described embodiments. The foregoing embodiments may be implemented individually or in any combination.

What is claimed is:

1. An electronic device, comprising:
a sensor; and
a display comprising pixels, wherein:
the pixels comprise subpixels;
the subpixels comprise emissive subpixels that emit light and thin-film transistor subpixels that control the emissive sub-pixels;
the emissive subpixels are arranged in a regular grid of rows and columns;
the display has a first portion that overlaps the sensor and a second portion that does not overlap the sensor;
the first portion comprises a plurality of subpixel groups that each include at least one subpixel;
each one of the plurality of subpixel groups in the first portion comprises a thin-film transistor subpixel that controls two or more emissive subpixels;
a total number of emissive subpixels per unit area is lower in the first portion than in the second portion; and
the emissive subpixels in the subpixel groups are part of the regular grid of rows and columns.

2. The electronic device defined in claim 1, wherein the thin-film transistor subpixel that controls two or more emissive subpixels controls two or more emissive subpixels of a same color.

3. The electronic device defined in claim 1, wherein the thin-film transistor subpixel is a first thin-film transistor subpixel that controls two blue emissive subpixels and wherein each one of the plurality of subpixel groups in the first portion comprises a second thin-film transistor subpixel that controls two red emissive subpixels.

4. The electronic device defined in claim 3, wherein each one of the plurality of subpixel groups in the first portion comprises a third thin-film transistor subpixel that controls a first green emissive subpixel, a fourth thin-film transistor subpixel that controls a second green emissive subpixel, and a fifth thin-film transistor subpixel that controls a third green emissive subpixel.

5. The electronic device defined in claim 3, wherein each one of the plurality of subpixel groups in the first portion comprises a third thin-film transistor subpixel that controls a first green emissive subpixel and a fourth thin-film transistor subpixel that controls a second green emissive subpixel.

6. The electronic device defined in claim 3, wherein each one of the plurality of subpixel groups in the first portion comprises a third thin-film transistor subpixel that controls three green emissive subpixels.

7. The electronic device defined in claim 3, wherein each one of the plurality of subpixel groups in the first portion comprises a third thin-film transistor subpixel that controls two green emissive subpixels.

8. The electronic device defined in claim 1, wherein the plurality of subpixel groups is arranged in a checkerboard layout and wherein each one of the plurality of subpixel groups has emissive subpixels in a same layout.

9. The electronic device defined in claim 1, wherein the plurality of subpixel groups is arranged in a checkerboard layout, wherein the plurality of subpixel groups comprises a first subset and a second subset, wherein each one of the first subset of the plurality of subpixel groups has emissive subpixels in a first layout, and wherein each one of the second subset of the plurality of subpixel groups has emissive subpixels in a second layout that is different than the first layout.

10. The electronic device defined in claim 9, wherein blue emissive subpixels in the first layout are changed to red emissive subpixels in the second layout and wherein red emissive subpixels in the first layout are changed to blue emissive subpixels in the second layout.

11. The electronic device defined in claim 9, wherein the first subset of the plurality of subpixel groups comprises every other row of subpixel groups in the checkerboard layout and wherein the second subset of the plurality of subpixel groups comprises remaining rows of subpixel groups in the checkerboard layout.

12. The electronic device defined in claim 1, wherein each one of the plurality of subpixel groups comprises seven emissive subpixels.

13. The electronic device defined in claim 12, wherein each one of the plurality of subpixel groups comprises five total thin-film transistor subpixels.

14. The electronic device defined in claim 12, wherein each one of the plurality of subpixel groups comprises three total thin-film transistor subpixels.

15. The electronic device defined in claim 1, wherein the display comprises:
a plurality of signal lines that provide signals to thin-film transistor subpixels in the second portion of the display, wherein the plurality of signal lines comprises a first subset that also provides signals to thin-film transistor subpixels in the first portion of the display, and wherein the plurality of signal lines comprises a second subset that is aligned with the first portion of the display but do not provide signals to any thin-film transistor subpixels in the first portion of the display.

16. The electronic device defined in claim 15, wherein the second subset of the plurality of signal lines is routed through the first portion of the display.

17. The electronic device defined in claim 15, wherein the second subset of the plurality of signal lines is routed around the first portion of the display.

18. The electronic device defined in claim 1, wherein each one of the plurality of subpixel groups in the first portion comprises at least one dummy subpixel.

19. An electronic device, comprising:
a sensor; and
a display comprising subpixels, wherein:
the subpixels comprise emissive subpixels that emit light and thin-film transistor subpixels that control the emissive sub-pixels;
the emissive subpixels are arranged in a regular grid of rows and columns;
the display has a first portion that overlaps the sensor and a second portion that does not overlap the sensor;
the first portion comprises a plurality of subpixel groups that each include a first thin-film transistor subpixel that controls two red emissive subpixels, a second thin-film transistor subpixel that controls two blue emissive subpixels, and a third thin-film transistor subpixel that controls three green emissive subpixels;
a total number of emissive subpixels per unit area is lower in the first portion than in the second portion; and
the emissive subpixels in the subpixel groups are part of the regular grid of rows and columns.

20. The electronic device defined in claim 19, wherein each subpixel group comprises four rows of subpixels and five columns of subpixels.

21. An electronic device, comprising:
a sensor; and
a display comprising subpixels, wherein:
the subpixels comprise emissive subpixels that emit light and thin-film transistor subpixels that control the emissive sub-pixels;
the emissive subpixels are arranged in a regular grid of rows and columns;
the display has a first portion that overlaps the sensor and a second portion that does not overlap the sensor;
the first portion comprises a plurality of subpixel groups that are arranged in a checkerboard layout, wherein no unoccupied rows of subpixels are interposed between adjacent rows of subpixel groups in the checkerboard layout and wherein no unoccupied columns of subpixels are interposed between adjacent columns of subpixel groups in the checkerboard layout;
a total number of emissive subpixels per unit area is lower in the first portion than in the second portion; and
the emissive subpixels in the subpixel groups are part of the regular grid of rows and columns.
